(19) United States
(12) Patent Application Publication
(10) Pub. No.: US 2021/0135142 A1
(43) Pub. Date: May 6, 2021

(54) ORGANIC ELECTROLUMINESCENT DEVICE BASED ON EXCIPLEX AND EXCIMER SYSTEM

(71) Applicant: JIANGSU SUNERA TECHNOLOGY CO., LTD., Wuxi (CN)

(72) Inventors: CHONG LI, WUXI (CN); ZHONGHUA YE, WUXI (CN); DANDAN TANG, WUXI (CN); XIAOQING ZHANG, WUXI (CN)

(21) Appl. No.: 17/128,133

(22) Filed: Dec. 20, 2020

Related U.S. Application Data
(63) Continuation of application No. PCT/CN2019/096495, filed on Jul. 18, 2019.

(30) Foreign Application Priority Data
Aug. 15, 2018 (CN) 201810927113.4

(51) Int. Cl. H01L 51/50; H01L 51/00

(52) U.S. Cl. CPC H01L 51/5012; H01L 51/0072; H01L 51/0052; H01L 51/0067; H01L 51/0069; H01L 51/0054; H01L 51/0071; H01L 51/008; H01L 51/006; H01L 2251/552; H01L 2251/5384; H01L 51/0073

(57) ABSTRACT

The present invention relates to an exciplex and excimer system-based organic electroluminescent device. The host material of the light emitting layer comprises first, second and third organic compounds. A mixture or lamination formed by the first and second organics produces an exciplex under light or electrical excitation. The third organic compound is doped in the mixture or a layer of the lamination formed by the first and second organic compounds, and the third organic compound forms an excimer. The singlet energy level of the exciplex is higher than the singlet energy level of the third organic compound, and the triplet energy level thereof is higher than the triplet energy level of the third organic compound. The device of the present invention has the characteristics of high efficiency and long service time.

### CROSS-REFERENCE TO RELATED APPLICATIONS

This application is a continuation of International Patent Application No. PCT/CN2019/096495 with a filing date of Jul. 18, 2019, designating the United States, now pending, and further claims priority to Chinese Patent Application No. 201810927113.4 with a filing date of Oct. 15, 2018. The content of the aforementioned applications, including any intervening amendments thereto, are incorporated herein by reference.

### TECHNICAL FIELD

The disclosure relates to the technical field of semiconductors, particularly to an organic electroluminescent device based on an exciplex and excimer system, which is high in efficiency and long in lifetime.

### BACKGROUND

The organic light-emitting diode (OLED) has been positively researched and developed. The simplest basic structure of an organic electroluminescent device includes a luminescent layer which is sandwiched between a cathode and an anode which are opposite. The organic electroluminescent device is considered as a next-generation panel display material to attract much attention because it can realize ultra-thin ultra-lightweight, fast input signal response speed and low-voltage direct-current drive.

It is generally believed that the organic electroluminescent device has the following luminescence mechanism: when a voltage is applied between electrodes sandwiched with the luminescent layer, electrons injected from the anode and holes injected from the cathode are recombined in the luminescent layer to form excitons, and the excitons are relaxed to a ground state to release energy to form photons. In the organic electroluminescent device, the luminescent layer usually requires that a guest material is doped in a host material to obtain more efficient energy transfer efficiency and gives full play to the luminescent potential of the guest material. In order to obtain high host and guest energy transfer efficiency, the matching of host and guest materials and the balance degree of electrons and holes inside the host material are key factors to obtain high-efficiency devices. The carrier mobility of electrons and holes inside the existing host material often has significant difference, which leads to a fact that the exciton recombination region deviates from the luminescent layer to result in low efficiency and poor stability of the existing device.

The application of organic light-emitting diodes (OLEDs) in the aspects of large-area panel display and illumination has attracted wide attention from industry and academia. However, the traditional organic fluorescent material can only utilize 25% singlet excitons formed by electrical excitation to emit light, and the internal quantum efficiency of the device is low (up to 25%). The external quantum efficiency is generally less than 5%, which is far from the efficiency of a phosphorescent device. Although the phosphorescent material can emit light by effectively utilizing singlet excitons and triplet excitons so that the internal quantum efficiency of the device is up to 100% because strong spin-orbit coupling in the center of heavy atoms enhances intersystem crossing, the phosphorescent material has some problems of expensive price, poor material stability, serious device efficiency drop and the like, thereby limiting its application in OLEDs.

The thermally activated delayed fluorescence (TADF) material is a third-generation organic luminescent material developed after the organic fluorescent material and the organic phosphorescent material. Such the material generally has a small singlet-triplet energy level difference (ΔEST), and triplet excitons can be converted into singlet excitons through the inverse intersystem crossing so as to emit light. This can make full use of singlet excitons and triplet excitons formed under electric excitation, and the internal quantum efficiency of the device can reach 100%. At the same time, the material has controllable structure, stable property, low price and no precious metals, and has a broad application prospect in the field of OLEDs. The TADF material mainly has two forms, one of them is intramolecular TADF, and the other is intermolecular TADF; the intramolecular TADF is mainly used as a doping luminescent material through upconversion of triplet excitons of the same molecule itself into singlet excitons; the intermolecular TADF is mainly used as the host material by realizing conversion of triplet excitons into singlet excitons via charge transfer between two different molecules.

Although the TADF material can achieve 100% of exciton utilization rate in theory, actually, there are some problems: (1) the T1 and S1 states of the molecule are designed to have strong CT characteristics and a very small S1-T1 state energy gap. Although the conversion rate of excitons in the T1→S1 state can be achieved through a TADF process, low S1 state radiation transition rate is simultaneously caused, thus it is difficult to simultaneously consider (or simultaneously realize) high exciton utilization rate and high fluorescent radiation efficiency;

(2) Because the TADF material with a D-A, D-A-D or A-D-A structure is used at present, the configurations of the molecule in ground and excited states greatly change due to its large molecular flexibility, and the full width at half maximum (FWHM) of the spectrum of the material is too large so as to lead to the reduced color purity of the material;

(3) Even if doping devices have been used to reduce the concentration quenching effect of T excitons, the devices made of most TADF materials have a serious efficiency drop at high current density.

(4) Due to different electron and hole transport rates of the host material, the traditional host and guest matching manner leads to reduction in carrier recombination rate and decrease in device efficiency; meanwhile, the carrier recombination region is close to one side of the host material so that the carrier recombination region is excessively centralized, resulting in excessive centralization of density of triplet excitons, an obvious carrier quenching phenomenon, and reduced device efficiency and lifetime.

The luminescent layer matching of the traditional device adopts a host and guest doping form, energy is transferred to the guest material through the host material so that the guest material emits light, thereby avoiding the concentration quenching of excitons and promoting the efficiency and lifetime of the device. However, there are still phenomena of insufficient carrier recombination and low device efficiency and lifetime. Meanwhile, the peak width at half height in the spectrum of the device is large, which is disadvantageous to improvement of the color purity of the device.

### SUMMARY

In view of the above problems existing in the prior art, the present application provides a high-efficiency organic electroluminescent device. In one aspect of the present application, the carriers inside the device can be effectively balanced, the quenching effect of the excitons is reduced, and the recombination rate of carriers is improved; meanwhile, the exciplex formed by first and second organic compounds is capable of effectively reducing a drive voltage and promoting the efficiency and work stability of the device; in another aspect, the excimer formed by a third organic compound is capable of effectively utilizing the energy of triplet excitons, reducing the quenching effect of the triplet excitons and improving the luminescent efficiency and stability of the device; on the one hand, the excimer is capable of effectively reducing the concentration of triplet excitons of the host material and reducing the singlet-exciton quenching and triplet-triplet quenching of the host material, and on the other hand, the triplet excitons and singlet excitons of the excimer are capable of promoting the thermal stability and chemical stability of the molecule due to being in a dual-molecule excited state form, so as to prevent the decomposition of the material; further, the excimer is capable of sufficiently transferring energy to the guest material through upconversion of the triplet excitons into singlet excitons, so that the singlet state and triplet state of the guest material are effectively utilized, thereby effectively promoting the luminescent efficiency and lifetime of the device; based on the above device matching, the efficiency and lifetime of the organic light-emitting device can be effectively improved.

The technical solution of the disclosure is as follows:

An organic electroluminescent device, comprising a cathode, an anode, a luminescent layer between the cathode and the anode, a hole transport region between the anode and the luminescent layer and an electron transport region between the cathode and the luminescent layer; the luminescent layer comprising a host material and a guest material; wherein the host material of the luminescent layer comprises a first organic compound, a second organic compound and a third organic compound, a difference between the HOMO energy level of the first organic compound and the HOMO energy level of the second organic compound is greater than or equal to 0.2 eV, and a difference between the LUMO energy level of the first organic compound and the LUMO energy level of the second organic compound is greater than or equal to 0.2 eV;

the first organic compound and the second organic compound form a mixture or a laminated interface which generates an exciplex under the condition of optical excitation or electric field excitation; the emission spectrum of the exciplex and the absorption spectrum of the third organic compound are overlapped; the singlet energy level of the exciplex is higher than that of the third organic compound, and the triplet energy level of the exciplex is higher than that of the third organic compound; and the first organic compound and the second organic compound have different carrier transport characteristics;

the third organic compound is doped into the mixture or laminated interface formed by the first and second organic compounds and forms an intramolecular excimer; the singlet energy level of the excimer is less than that of the exciplex, and the triplet energy level of the excimer is less than that of the exciplex;

the guest material in the luminescent layer is a fluorescent organic compound, the singlet energy level of the guest material is less than that of the excimer, and the triplet energy level of the guest material is less than that of the excimer.

Preferably, 0.3 eV≤|HOMO_{second organic compound}|−|HOMO_{first organic compound}|≤1.0 eV; 0.3 eV≤|LUMO_{second organic compound}|−|LUMO_{first organic compound}|≤1.0 eV; |HOMO_{third organic compound}|<|HOMO_{second organic compound}|, |LUMO_{third organic compound}|>|LUMO_{first organic compound}|; wherein |HOMO| and |LUMO| represent absolute values of the energy levels of the compounds.

Preferably, a difference between the triplet energy level and the singlet energy level of the exciplex formed by the first organic compound and the second organic compound is less than or equal to 0.2 eV.

Preferably, the third organic compound forms the excimer, and a difference between the triplet energy level and the singlet energy level of the excimer is less than or equal to 0.2 eV.

Preferably, the first organic compound and the second organic compound form a mixture in a mass ratio of 1:99˜99:1; the third organic compound is doped into the mixture formed by the first and second organic compounds; and a mass ratio of the third organic compound to the mixture formed by the first and second organic compounds is 1:99˜50:50.

Preferably, the first organic compound and the second organic compound form a laminated structure having an interface, the first organic compound is located at a hole transport side, and the second organic compound is located at an electron transport side; the third organic compound is doped into the first organic compound layer or second organic compound layer, and a mass ratio of the third organic compound to the first organic compound is 1:99˜50:50, or a mass ratio of the third organic compound to the second organic compound is 1:99˜50:50.

Preferably, in the luminescent layer, the guest material is 0.5%˜15% by mass of the host material.

Preferably, the hole mobility of the first organic compound is greater than an electron mobility, and the electron mobility of the second organic compound is greater than the hole mobility; and the first organic compound is a hole transfer type material, and the second organic compound is an electron transfer type material.

Preferably, a difference between the singlet energy level and the triplet energy level of the guest material is less than or equal to 0.3 eV.

Preferably, the third organic compound is a compound containing boron atoms; wherein the quantity of boron atoms is greater than or equal to 1, and the boron atoms are bonded with other elements through sp2 hybrid orbits;

a group connected with boron is one of a hydrogen atom, substituted or unsubstituted C1-C6 linear alkyl, substituted or unsubstituted C3-C10 cycloalkyl, substituted or unsubstituted C1-C10 heterocycloalkyl, substituted or unsubstituted C6-C60 aryl, and substituted or unsubstituted C3-C60 heteroaryl;

furthermore, the groups connected with boron atoms can be connected alone, or mutually and directly bonded to form a ring, or connected with boron after being connected with other groups to form the ring.

Preferably, the quantity of boron atoms contained in the third organic compound is 1, 2 or 3.

Preferably, the third organic compound has a structure as shown in general formula (1):

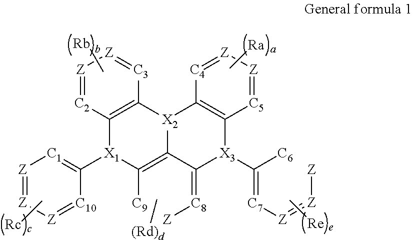

wherein, X₁, X₂ and X₃ each independently represent a nitrogen atom or a boron atom, and at least one of X₁, X₂ and X₃ is the boron atom; Z, on each occurrence, identically or differently represents N or C(R);

a, b, c, d and e each independently represent 0, 1, 2, 3, or 4;

at least one pair of C₁ and C₂, C3 and C₄, C₅ and C₆, C₇ and C₈, and C₉ and C₁₀ can be connected to form a 5 to 7 membered ring structure;

R, on each occurrence, identically or differently represents H, D, F, Cl, Br, I, C(═O)R¹, CN, Si(R¹)₃, P(═O) (R¹)₂, S(═O)₂R¹, linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, SO or SO₂, and wherein one or more H atoms in the groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;

R¹, on each occurrence, identically or differently represents H, D, F, Cl, Br, I, C(═O)R², CN, Si(R²)₃, P(═O)(R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the above groups can be substituted by —R²C═CR²—, —C≡C—, Si(R²)₂, C(═O), C═NR², —C(═O)O—, C(═O)NR²—, NR², P(═O)(R²), —O—, —S—, SO or SO₂, and wherein one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, and the group can be substituted by one or more groups R², wherein two or more groups R¹ can be connected to each other and form a ring;

R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;

Ra, Rb, Rc and Rd each independently represent C1-C20 alkyl, branched C3-C20 alkaly or C3-C20 cycloalkyl, linear or branched C1-C20 alkyl substituted silyl, substituted or unsubstituted C6-C30 aryl, substituted or unsubstituted 5 to 30 membered heteroaryl, and substituted or unsubstituted C5-C30 arylamino;

under the condition that Ra, Rb, Rc and Rd groups are bonded with Z, Z is equal to C.

Preferably, the third organic compound has a structure as shown in general formula (2):

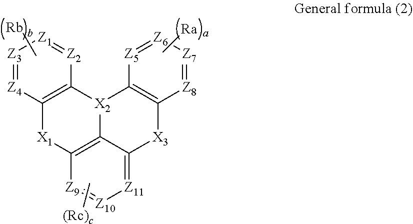

wherein, X₁ and X₃ each independently represent a single bond, B(R), N(R), C(R)₂, Si(R)₂, O, C═N(R), C═C(R)₂, P(R), P(═O)R, S or SO₂; X₂ independently represents a nitrogen atom or a boron atom, and at least one of X₁, X₂ and X₃ is the boron atom;

Z₁-Z₁₁ independently represent the nitrogen atom or C(R), respectively;

a, b and c each independently represent 0, 1, 2, 3, or 4;

R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the above groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, SO or SO₂, and wherein one or more H atoms in the above groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;

R¹, on each occurrence, identically or differently represents H, D, F, Cl, Br, I, C(═O)R², CN, Si(R²)₃, P(═O)(R₂)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the above groups can be substituted by —R₂C═CR₂—, —C≡C—, Si(R²)₂, C(═O), C═NR², —C(═O)O—, C(═O)NR²—, NR², P(═O)(R²), —O—, —S—, SO or SO₂, and wherein one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;

R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;

Ra, Rb and Rc each independently represent C1-C20 alkyl, branched C3-C20 alkyl or cycloalkyl, linear or branched C1-C20 alkyl substituted silyl, substituted or unsubstituted C6-C30 aryl, substituted or unsubstituted 5 to 30 membered heteroaryl, and substituted or unsubstituted C5-C30 arylamino;

under the condition that Ra, Rb and Rc groups are bonded with Z, Z is equal to C.

Preferably, the third organic compound has a structure as shown in general formula (3):

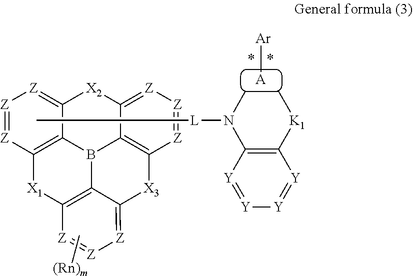

wherein, X₁, X₂ and X₃ each independently represent a single bond, B(R), N(R), C(R)₂, Si(R)₂, O, C═N(R), C═C(R)₂, P(R), P(═O)R, S or SO₂;

Z and Y at different positions independently represent C(R) or N, respectively;

K₁ represents one of a single bond, B(R), N(R), C(R)₂, Si(R)₂, O, C═N(R), C═C(R)₂, P(R), P(═O)R, S or SO₂, C1-C20 alkyl substituted alkylene, C1-C20 alkyl substituted silyl and C6-C20 aryl substituted alkylene;

[symbol] represents an aromatic group having a carbon atom number of 6˜20 or a heteroaromatic group having a carbon atom number of 3˜20;

m represents 0, 1, 2, 3, 4 or 5; L is selected from a single bond, a double bond, a triple bond, an aryl group having carbon atom number of 6˜40 or a heteroaromatic group having carbon atom number of 3˜40;

R, on each occurrence, identically or differently represents H, D, F, Cl, Br, I, C(═O)R¹, CN, Si(R¹)₃, P(═O) (R¹)₂, S(═O)₂R¹, linear C1-C20 alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, SO or SO₂, and wherein one or more H atoms in the above groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring:

R¹, on each occurrence, identically or differently represents H, D, F, Cl, Br, I, C(═O)R², CN, Si(R²)₃, P(═O)(R²)₂, N(R²)S(═O)₂R², linear C1-C20 alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R²C═CR²—, —C≡C—, Si(R²)₂, C(═O), C═NR², —C(═O)O—, C(═O)NR²—, NR², P(═O)(R²), —O—, —S—, SO or SO₂, and wherein one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;

R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;

Rₙ independently represents substituted or unsubstituted C1-C20 alkyl, C1-C20 alkyl substituted silyl, substituted or unsubstituted C6-C30 aryl, substituted or unsubstituted 5 to 30 membered heteroaryl, and substituted or unsubstituted C5-C30 arylamino, respectively;

Ar represents substituted or unsubstituted C1-C20 alkyl, C1-C20 alkyl substituted silyl, substituted or unsubstituted C6-C30 aryl, substituted or unsubstituted 5 to 30 membered heteroaryl, and substituted or unsubstituted C5-C30 arylamino or a structure shown in general formula (4):

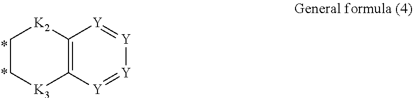

K₂ and K₃ independently represent one of a single bond, B(R), N(R), C(R)₂, Si(R)₂, O, C═N(R), C═C(R)₂, P(R), P(═O)R, S, S═O or SO₂, C1-C20 alkyl substituted alkylene, C1-C20 alkyl substituted silanylene and C6-C20 aryl substituted alkylene, respectively;

* represents ligation sites of general formula (4) and general formula (3).

More preferably, in general formula (3), X₁, X₂ and X₃ each can also be independently absent, namely, none of atoms or bond linkages is each independently present at the positions represented by X₁, X₂ and X₃, and the atom or bond is present at the position of at least one of X₁, X₂ and X₃.

Preferably, the guest material is as shown in general formula (5):

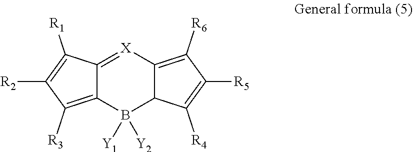

wherein, X represents a N atom or C—R₇;

R₁˜R₇ independently represent one of a hydrogen atom, substituted or unsubstituted C1-C20 alkyl, substituted or unsubstituted C3-C20 cycloalkyl, substituted or unsubstituted 3 to 20 membered heterocyclyl, substituted or unsubstituted C2-C20 alkylene, substituted or unsubstituted C3-C20 alkenyl, substituted or unsubstituted alkynyl, substituted or unsubstituted hydroxy, substituted or unsubstituted alkoxyl, substituted or unsubstituted alkyl sulfide group, substituted or unsubstituted C6-C30 aryl, substituted or unsubstituted 5 to 30 membered heteroaryl, halogens, cyan, substituted or unsubstituted aldehyde group, substituted or unsubstituted carbonyl, substituted or unsubstituted carboxyl, substituted or unsubstituted oxycarbonyl, substituted or unsubstituted amido, substituted or unsubstituted amino, substituted or unsubstituted nitro, substituted or unsubstituted silyl, substituted or unsubstituted silyloxy, substituted or unsubstituted boryl and substituted or unsubstituted phosphine oxide;

R₁˜R₇ are each identical or different, and meanwhile R₁ and R₂, R₂ and R₃, R₄ and R₅, and R₅ and R₆ can be mutually bonded to form a cyclic structure having an atom number of 5˜30;

Y₁ and Y₂ can be identical or different; Y₁ and Y₂ independently represent one of substituted or unsubstituted C1-C20 alkyl, substituted or unsubstituted C3-C20 cycloalkyl, substituted or unsubstituted 3 to 20 membered heterocyclyl, substituted or unsubstituted C2-C20 alkylene, substituted or unsubstituted C3-C20 alkenyl, substituted or unsubstituted alkynyl, substituted or unsubstituted hydroxy, substituted or unsubstituted alkoxyl, substituted or unsubstituted alkyl sulfide group, substituted or unsubstituted C6-C30 aryl, substituted or unsubstituted 5 to 30 membered heteroaryl, halogens, cyan, substituted or unsubstituted aldehyde group, substituted or unsubstituted carbonyl, substituted or unsubstituted carboxyl, substituted or unsubstituted oxycarbonyl, substituted or unsubstituted amido, substituted or unsubstituted amino, substituted or unsubstituted nitro, substituted or unsubstituted silyl, substituted or unsubstituted silyloxy, substituted or unsubstituted boryl and substituted or unsubstituted phosphine oxide, respectively.

More preferably, in general formula (5), Y1 and Y2 independently represent one of a fluorine atom, methoxyl, trifluromethyl, cyan and phenyl;

Preferably, the hole transport region comprises a combination of one or more of a hole injection layer, a hole transport layer and an electron barrier layer.

Preferably, the electron transport region comprises a combination of one or more of an electron injection layer, an electron transport layer and a hole barrier layer.

The present application also provides an illumination or display element, comprising one or more organic electroluminescent devices as described above; and under the condition that multiple devices are contained, the devices are horizontally or longitudinally overlapped and combined.

In the context of the disclosure, unless otherwise noted, HOMO means the highest occupied molecular orbit of a molecule, and LUMO means the lowest molecular orbit of the molecule. In addition, “LUMO energy level difference” involved in the specification means a difference between absolute values of various energy values. The full width at half maximum (FWHM) of the spectrum refers to a spectrum.

In the context of the disclosure, unless otherwise stated, the singlet (S1) energy level refers to the lowest excited energy level of the singlet state of the molecule, the triplet (T1) energy level refers to the lowest excited energy level of the triplet state of the molecule. In addition, the “triplet energy level difference value” and “singlet and triple energy level difference value” involved in the specification refer to a difference of the absolute value of each energy. In addition, the difference value between levels is expressed with an absolute value.

Preferably, the first organic compound and the second organic compound constituting the host material are independently selected from H1, H2, H3, H4, H5, H6, H7 and H8 respectively, but are not limited to the above materials, and their structures are as follows:

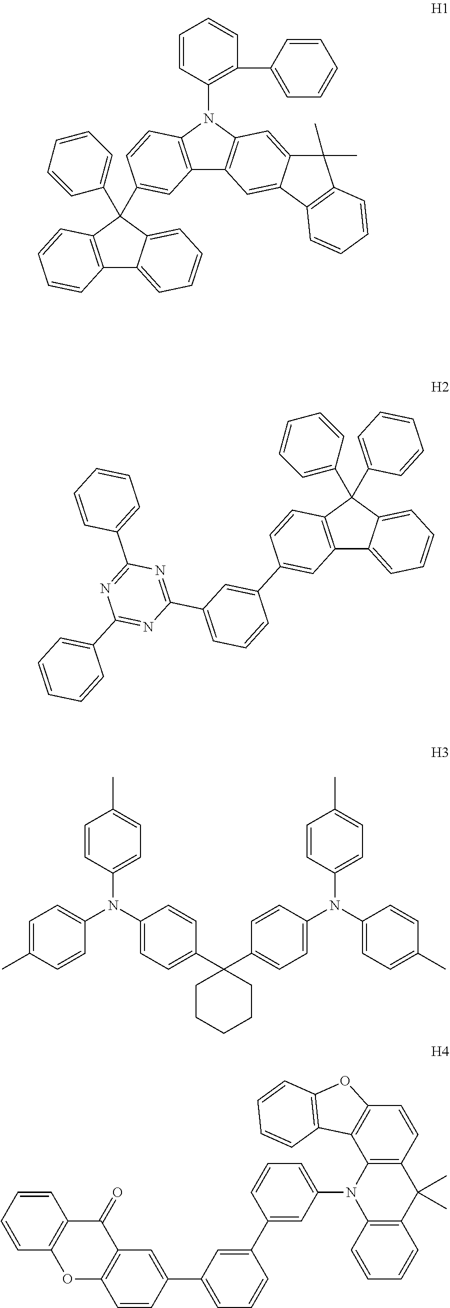

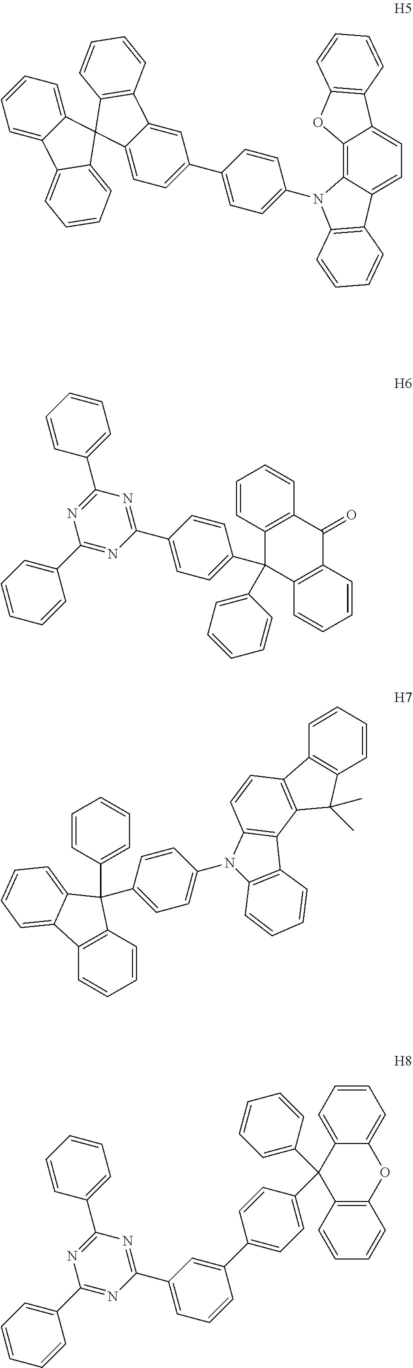 [SMILES: c1ccc2c(c1)-c1ccccc1C21c2ccccc2-c2cc(-c3ccc(-n4c5ccccc5c5ccc6c7ccccc7oc6c54)cc3)ccc21 ; O=C1c2ccccc2C(c2ccccc2)(c2ccc(-c3nc(-c4ccccc4)nc(-c4ccccc4)n3)cc2)c2ccccc21 ; CC1(C)c2ccccc2-c2ccc3c(c21)c1ccccc1n3-c1ccc(C2(c3ccccc3)c3ccccc3-c3ccccc32)cc1 ; c1ccc(-c2nc(-c3ccccc3)nc(-c3cccc(-c4ccc(C5(c6ccccc6)c6ccccc6Oc6ccccc65)cc4)c3)n2)cc1]

A difference between the HOMO/LUMO energy levels of the first organic compound and the second organic compound is greater than or equal to 0.2 eV. If the mixture or interface formed by the first organic compound and the second organic compound can form the exciplex under optical excitation, it can also generate the exciplex under electric field excitation; the exciplex cannot be generated under optical excitation, but the exciplex is generated under electric field excitation, as long as the difference between HOMO/LUMO energy levels between the first organic compound and the second organic compound meets requirements.

Preferably, in the host material of the luminescent layer, the first organic compound and the second organic compound form the mixture, wherein the mass percentage of the first organic compound is 10%˜90%, for example can be 9:1˜1:9, preferably 8:2˜2:8, preferably 7:3˜3:7, more preferably 1:1.

Preferably, the singlet energy level of the third organic compound is less than that of the exciplex, and the triplet energy level of the third organic compound is less than that of the exciplex.

Preferably, the third organic compound can be selected from the following compounds, but are not limited thereto:

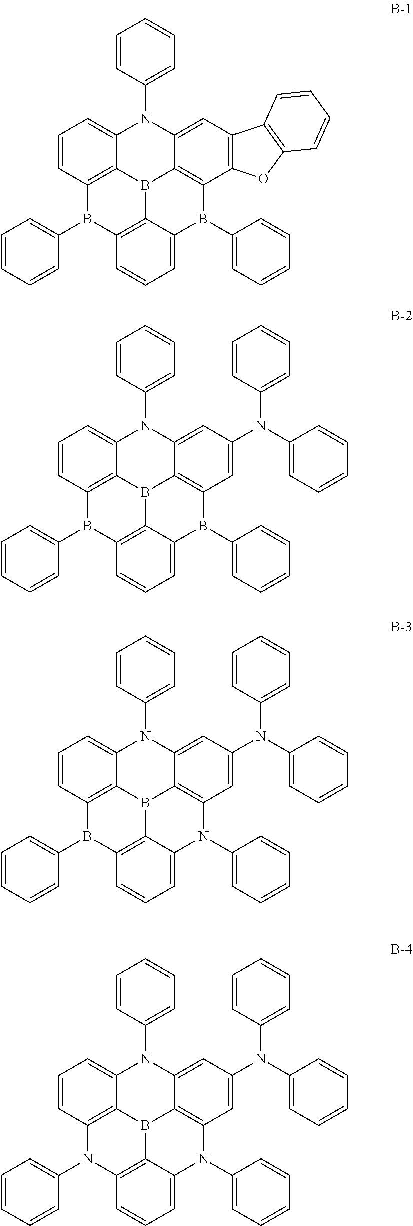

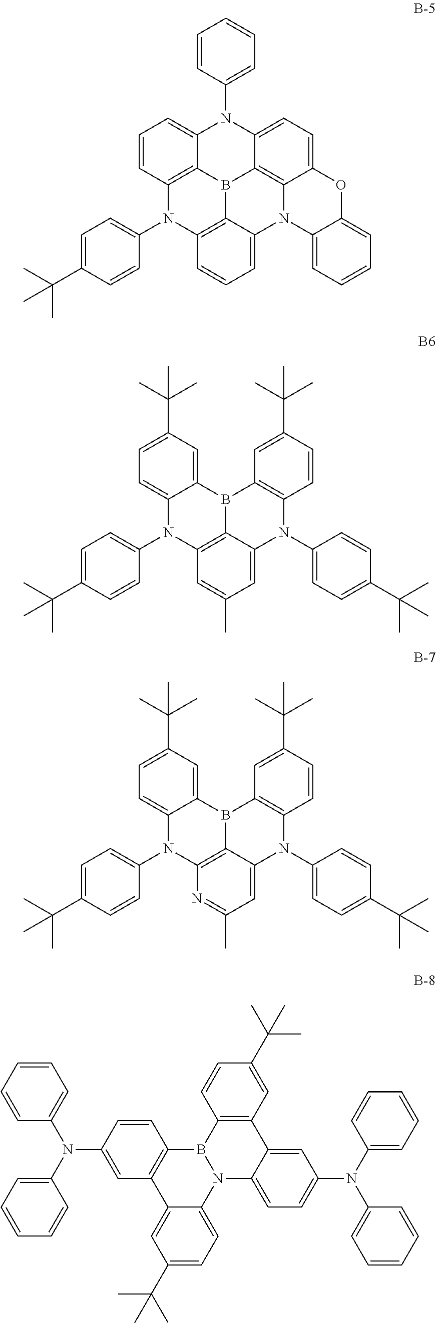

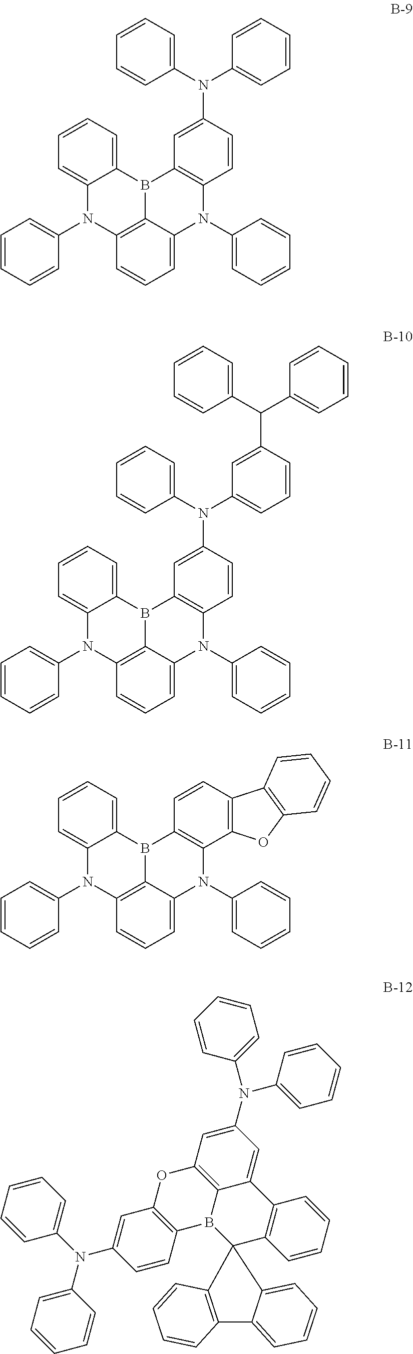 [SMILES: c1ccc(N(c2ccccc2)c2ccc3c(c2)B2c4ccccc4N(c4ccccc4)c4cccc(c42)N3c2ccccc2)cc1 ; c1ccc(C(c2ccccc2)c2cccc(N(c3ccccc3)c3ccc4c(c3)B3c5ccccc5N(c5ccccc5)c5cccc(c53)N4c3ccccc3)c2)cc1 ; c1ccc(N2c3ccccc3B3c4ccc5c(oc6ccccc65)c4N(c4ccccc4)c4cccc2c43)cc1 ; c1ccc(N(c2ccccc2)c2ccc3c(c2)Oc2cc(N(c4ccccc4)c4ccccc4)cc4c2B3C2(c3ccccc3-c3ccccc32)c2ccccc2-4)cc1]

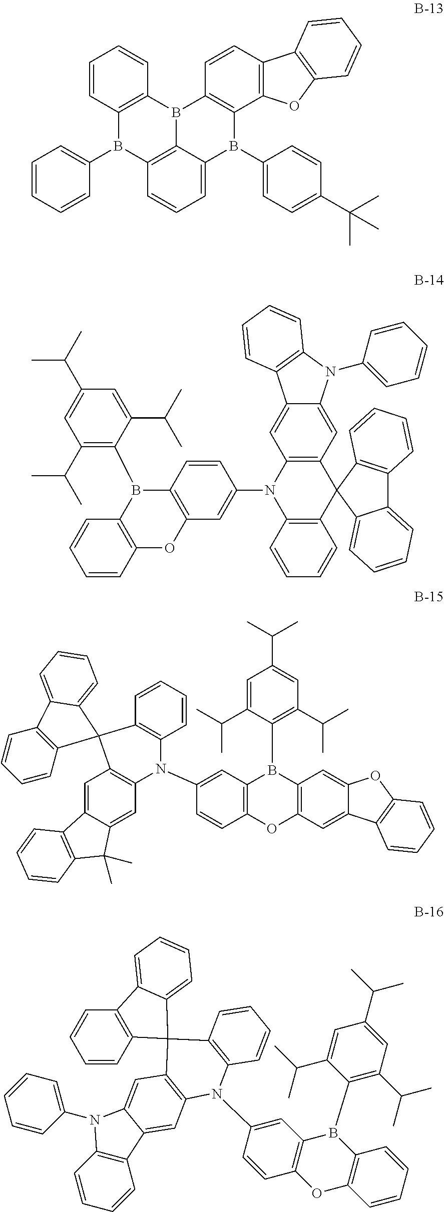

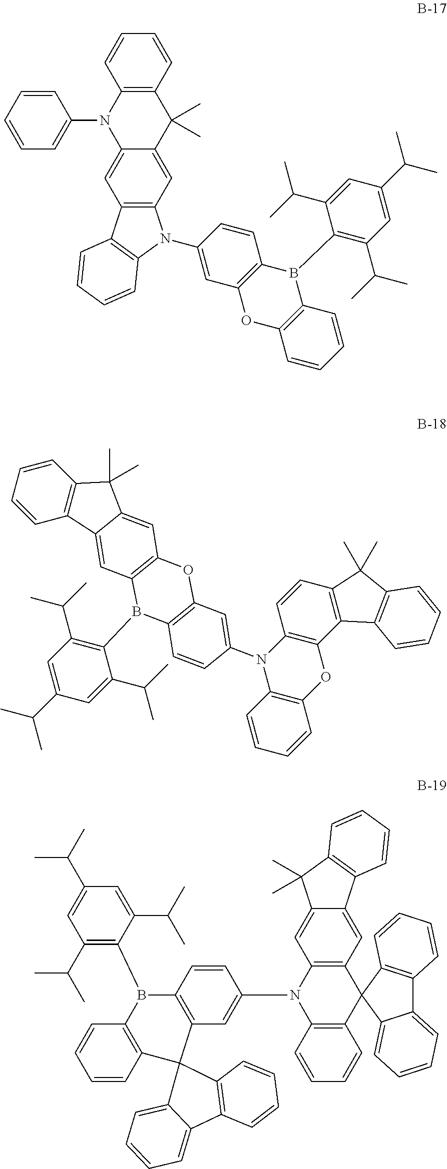

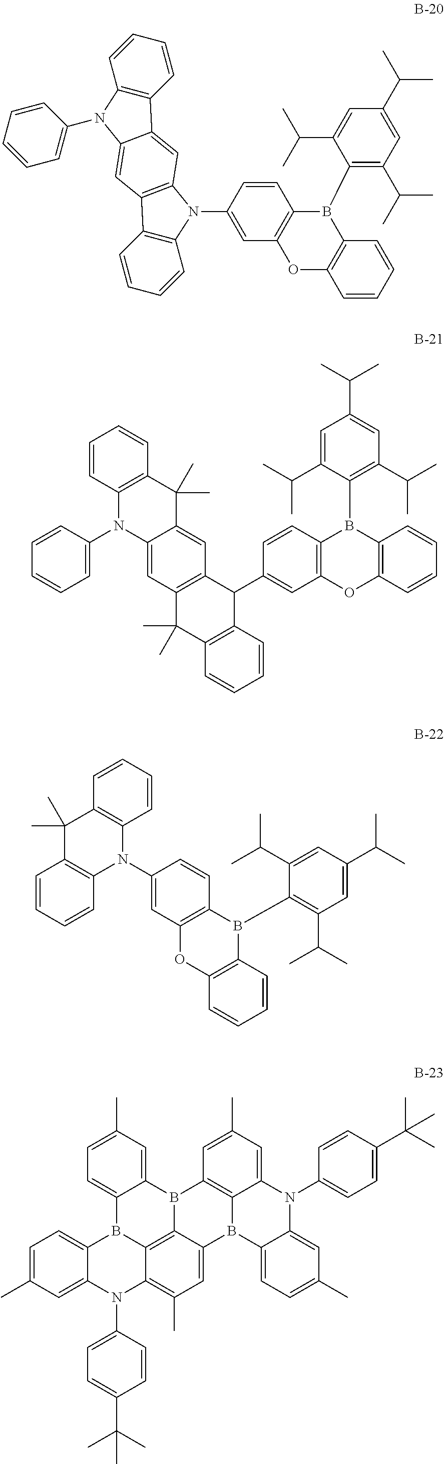

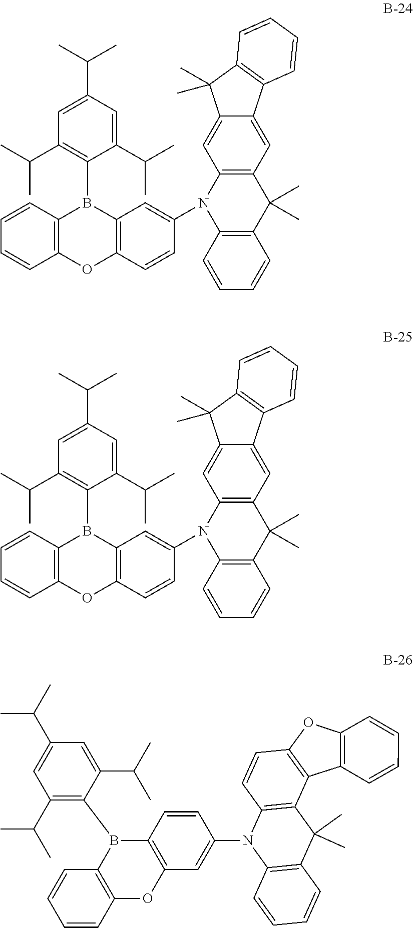

More preferably, the third organic compound is selected from the following compounds:

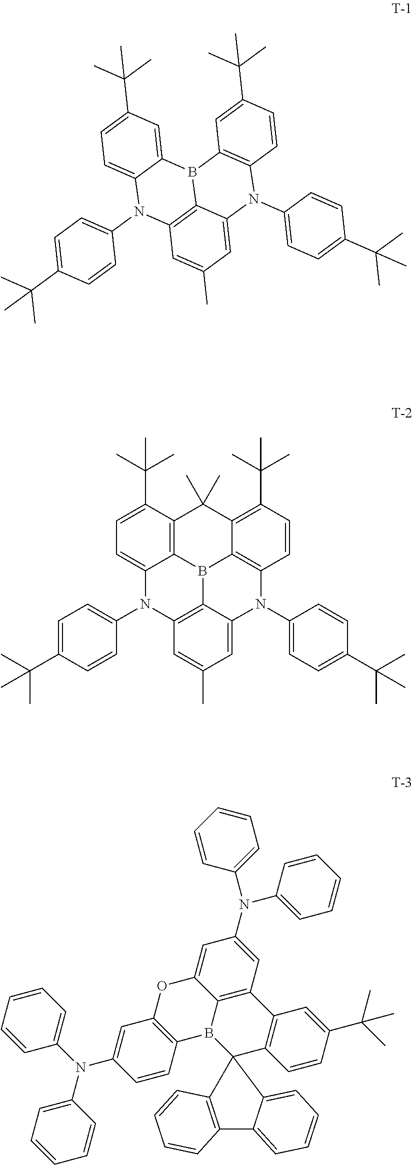

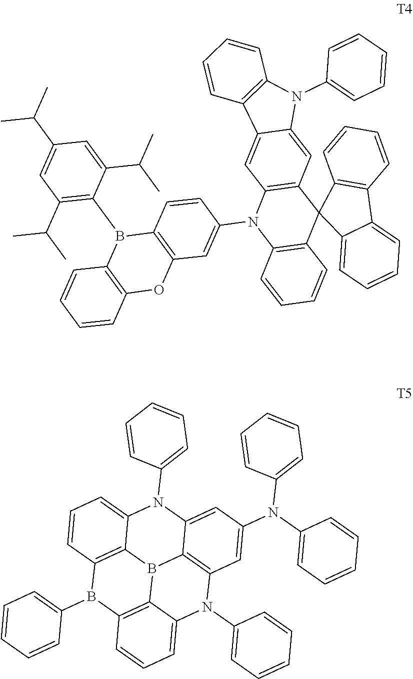 [SMILES: CC(C)c1cc(C(C)C)c(B2c3ccccc3Oc3cc(N4c5ccccc5C5(c6ccccc6-c6ccccc65)c5cc6c(cc54)c4ccccc4n6-c4ccccc4)ccc32)c(C(C)C)c1 ; c1ccc(B2c3cccc4c3B3c5c2cccc5N(c2ccccc2)c2cc(N(c5ccccc5)c5ccccc5)cc(c23)N4c2ccccc2)cc1]

Preferably, the mass percentage of the third organic compound relative to the host material is 5-30%, preferably 10-20%.

Preferably, the guest material is a fluorescent compound, which can be selected from the following compounds, but are not limited thereto:

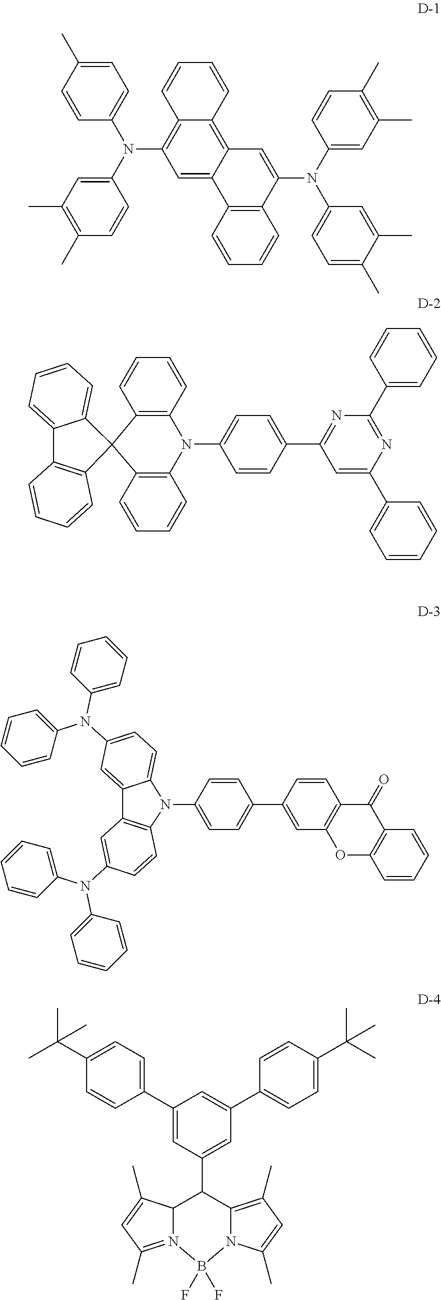

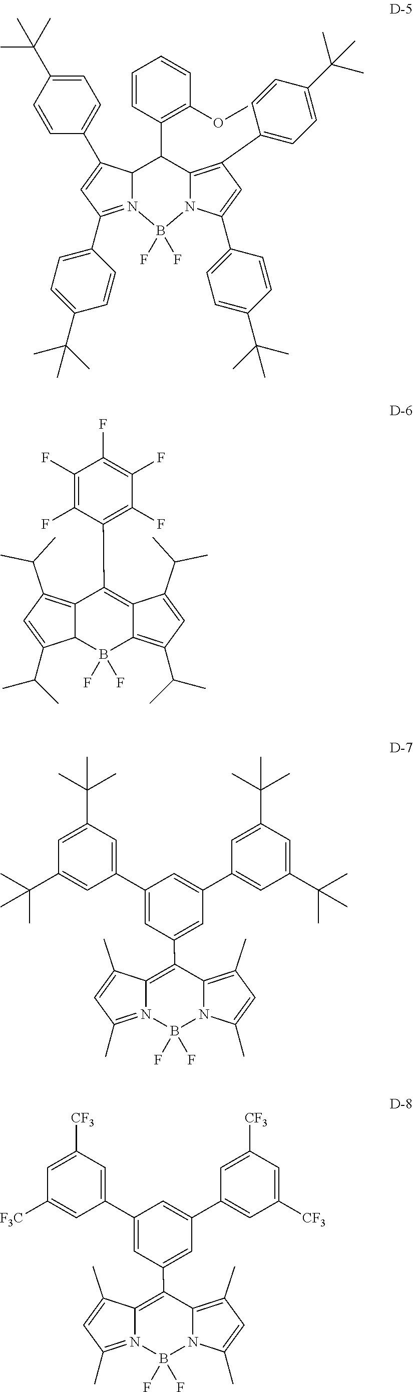

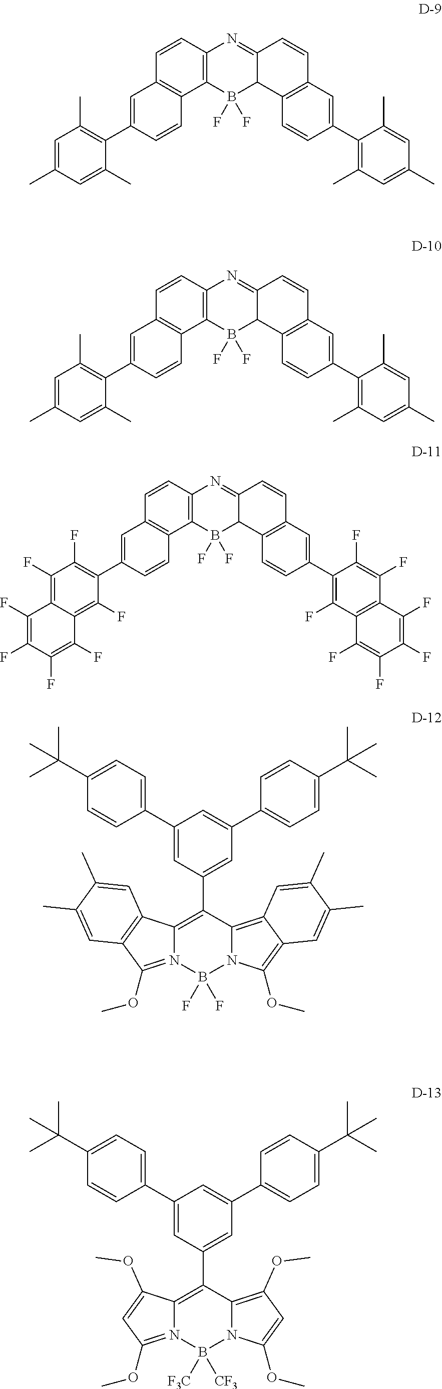

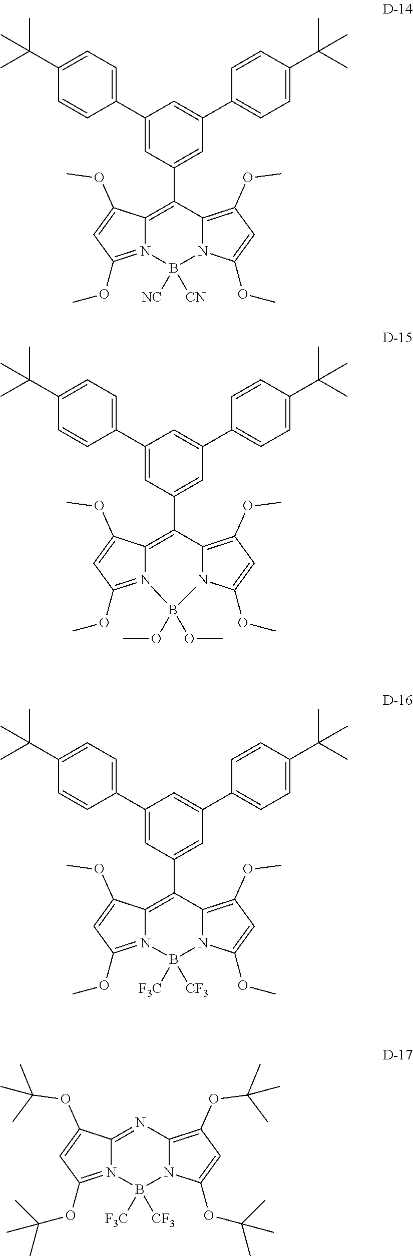

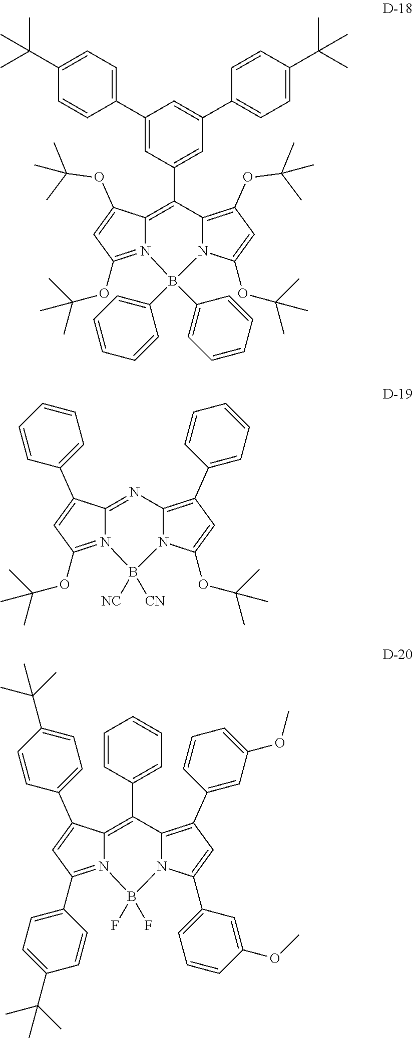

Preferably, the mass percentage of the guest material relative to the host material is 0.5-15%, preferably 0.5-5%.

On the other hand, the organic electroluminescent device of the disclosure also comprises a cathode and an anode.

Preferably, the anode comprises a metal, a metal oxide or a conducting polymer. For example, the work function of the anode ranges from about 3.5 eV to about 5.5 eV. The conducting materials for the anode comprise carbon, aluminum, vanadium, chromium, copper, zinc, silver, gold, other metals and their alloys; zinc oxide, indium oxide, tin oxide, indium tin oxide (ITO), indium zinc oxide and other similar metal oxides; and mixtures of oxides and metals, for example ZnO:Al and SnO₂:Sb. Both of transparent and non-transparent materials can be used as anode materials. For a structure emitting light to the anode, a transparent anode can be formed. In this paper, transparency means the pervious degree of light emitted from an organic material layer, and the perviousness of light has no specific limitation.

For example, when the organic light-emitting device described in this specification is of a top light-emitting type and the anode is formed on a substrate before the organic material layer and the cathode are formed, both of transparent materials and non-transparent materials having excellent light reflection can be used as anode materials. Alternatively, when the organic light-emitting device in this specification is of a bottom light-emitting type and the anode is formed on the substrate before the organic material layer and the cathode are formed, it is needed that the transparent material is used as the anode material, or the non-transparent material needs to be formed into a film which is thin enough to be transparent.

Preferably, for the cathode, a material having small work function is preferably used as the cathode material so as to easily conduct electron injection. Materials with work functions ranging from 2 eV to 5 eV can be used as cathode materials. The cathode can include metals such as magnesium, calcium, sodium, potassium, titanium, indium, yttrium, lithium, gadolinium, aluminum, silver, tin and lead or alloys thereof; materials having a multilayer structure, such as LiF/Al or LiO₂/Al, but are not limited to thereto. The cathode can use the same material as the anode, in this case, the cathode can be formed using the anode material as described above. In addition, the cathode or the anode can contain the transparent material.

According to the used material, the organic light-emitting device of the disclosure can be of top light-emitting type, bottom light-emitting type or two-side light-emitting type.

Preferably, the organic light-emitting device of the disclosure comprises a hole injection layer. The hole injection layer can be preferably disposed between the anode and the luminescent layer. The hole injection layer is formed from a hole injection material known to those skilled in the art. The hole injection material is a material which can easily receive holes from the anode under low voltage, and the HOMO energy level of the hole injection material is preferably located between the work function of the anode material and the HOMO of a surrounding organic material layer. Specific examples of the hole injection material include, but are not limited to, metalloporphyrin organic materials, oligothiophene organic materials, aromatic amine organic materials, hexanitrile hexaazabenzophenanthrene organic materials, quinacridone organic materials, perylene organic materials, anthraquinone conducting polymers, polyaniline conducting polymers or polythiophene conducting polymers.

Preferably, the organic light-emitting device of the disclosure comprises a hole transport layer. The hole transport layer can be preferably disposed between the hole injection layer and the luminescent layer, or between the anode and the luminescent layer. The hole transport layer is formed from a hole transport material known to those skilled in the art. The hole transport material is preferably a material with high hole mobility, which can transfer holes from the anode or hole injection layer to the luminescent layer. Specific examples of hole transport material include, but are not limited to, aromatic amine organic materials, conducting polymers, and block copolymers with jointing portions and non-jointing portions.

Preferably, the organic light-emitting device of the disclosure also comprises an electron barrier layer. The electron barrier layer can be preferably disposed between the hole transport layer and the luminescent layer, or between the hole injection layer and the luminescent layer, or between the anode and the luminescent layer. The electron barrier layer is formed from an electron barrier material, such as TCTA, known to those skilled in the art.

Preferably, the organic light-emitting device of the disclosure comprises an electron injection layer. The electron injection layer can be preferably disposed between the cathode and the luminescent layer. The electron injection layer is formed from an electron injection material known to those skilled in the art. The electron injection layer can be formed using an electron accepting organic compound. Here, as the electron accepting organic compounds, the known and optional compounds can be used without special limitations. As such the organic compounds, polycyclic compounds, such as p-terphenyl or quaterphenyl or derivatives thereof; polycyclic hydrocarbon compounds, such as naphthalene, tetracene, perylene, hexabenzobenzene, chrysene, anthracene, diphenyl anthracene or phenanthrene, or derivatives thereof; or heterocyclic compounds, such as phenanthroline, bathophenanthroline, phenanthridine, acridine, quinoline, quinoxaline or phenazine, or derivatives thereof can be used. The electron injection layer can also be formed using inorganic compounds, including but not limited to, magnesium, calcium, sodium, potassium, titanium, indium, yttrium, lithium, gadolinium, ytterbium, aluminum, silver, tin and lead or their alloys; LiF, LiO₂, LiCoO₂, NaCl, MgF₂, CSF, CaF₂, BaF₂, NaF, RbF, CsCl, Ru₂CO₃, YbF₃ or the like; and materials with multilayer structures, such as LiF/Al or LiO₂/Al.

Preferably, the organic light-emitting device of the disclosure comprises an electron transport layer. The electron transport layer can be preferably disposed between the electron injection layer and the luminescent layer, or between the cathode and the luminescent layer. The electron transport layer is formed from an electron transport material known to those skilled in the art. The electron transport material is a material that can easily accept electrons from the cathode and transfer the accepted electrons to the luminescent layer. Materials with high electron mobility are preferred. Specific examples of the electron transport material include, but are not limited to, 8-hydroxyquinoline aluminum complexes; complexes containing 8-hydroxyquinoline aluminum; organic free radical compounds; and hydroxyflavone metal complexes; and TPBi.

Preferably, the organic light-emitting device of the disclosure also comprises a hole barrier layer. The hole barrier layer can be preferably disposed between the electron transport layer and the luminescent layer, or between the electron injection layer and the luminescent layer, or between the cathode and the luminescent layer. The hole barrier layer is a layer that prevents the injected holes from passing through the luminescent layer to the cathode, and usually can be formed under the same conditions as those of hole injection layer. Specific examples include oxadiazole derivatives, triazole derivatives, phenanthroline derivatives, BCP, aluminum complexes, but are not limited to thereto.

Preferably, the hole barrier layer and the electron transport layer can be the same layer.

In addition, preferably, the organic light-emitting device can also comprise a substrate. Specifically, in the organic light-emitting device, the anode or cathode can be located on the substrate. For the substrate, there is no special limitation. The substrate can be a rigid substrate, such as a glass substrate, or a flexible substrate, such as a flexible film-shaped glass substrate, a plastic substrate or a film-shaped substrate.

The organic light-emitting device of the disclosure can be produced using the same materials and methods known in the art. Specifically, the organic light-emitting device can be produced by depositing metals, conducting metal oxides or their alloys on the substrate using a physical vapor deposition (PVD) method (e.g., sputtering or electron beam evaporation) to form the anode, forming an organic material layer comprising the hole injection layer, the hole transport layer, the electron barrier layer, the luminescent layer and the electron transport layer on the anode and subsequently depositing a material that can be used to form the cathode on the organic material layer. In addition, the organic light-emitting device can be fabricated by sequentially depositing the cathode material, one or more organic material layers and the anode material on the substrate. In addition, during the manufacturing of the organic light-emitting device, except the physical vapor deposition method, the organic light-emitting composite material of the disclosure can be made into the organic material layer by using a solution coating method. As used in this specification, the term “solution coating method” refers to rotary coating, dip coating, scraper coating, inkjet printing, screen printing, spraying, roller coating, but is not limited to thereto.

As for the thickness of each layer, there are no specific limitations, it can be determined by those skilled in the art according to the needs and specific circumstances.

Preferably, the thickness of the luminescent layer and the thicknesses of the optional hole injection layer, hole transport layer, electron barrier layer, electron transport layer and electron injection layer are respectively 0.5˜150 nm, preferably 1˜100 nm.

Preferably, the thickness of the luminescent layer is 20˜80 nm, more preferably 30˜60 nm.

The disclosure has the beneficial effects:

The host material of the luminescent layer of the organic electroluminescent device provided by the disclosure is formed by matching three materials, wherein the mixture or interface formed by the first and second organic compounds can produce exciplexes under the conditions of optical excitation and electric excitation, which can decrease the concentration of triplet excitons of the host material, reduce the quenching effect of triplet excitons, and improve the stability of the device.

The second compound is a material with a carrier mobility different from that of the first compound, which can balance the carriers inside the host material, increase the exciton recombination region, and improve the efficiency of the device while effectively solving the problem of color shift of the material under high current density, and improving the stability of the light-emitting color of the device.

The formed exciplex has a small triplet energy level and singlet energy level difference so that the triplet excitons can be rapidly converted into the triplet excitons, the quenching effect of the triplet excitons is reduced, and the stability of the device is promoted. Meanwhile, the singlet energy level of the formed exciplex is higher than that of the guest material, and the triplet energy level of the formed exciplex is higher than that of the guest material, which can effectively prevent energy from being transferred back to the host material from the guest material so as to further improve the efficiency and stability of the device.

The third organic material is an organic compound containing boron atoms, is bonded with other atoms through a sp2 hybrid form of boron. In the formed structure, since boron is an electron deficient atom, it has a strong electron absorption ability, thereby increasing an intermolecular Coulomb force; meanwhile, due to the presence of boron atoms, intermolecular rigidity is enhanced; the material easily forms a molecular aggregation effect, and excimer luminescence is easily generated.

The third organic compound is doped into the mixture or interface (doped into the first organic compound or second organic compound) formed by the first and second organic compounds, energy is transferred to the third organic compound from the exciplex formed by the first and second organic compounds, the excimer formed by the third organic compound can effectively reduce the concentration of the triplet excitons of the host material and decrease the singlet-exciton quenching and triplet-triplet quenching of the host material.

Due to being dual-molecule excitation forms, the triplet excitons and singlet excitons of the excimer can promote the thermal stability and chemical stability of the molecule and prevent the decomposition of the material. Further, the excimer is capable of sufficiently transferring energy to the guest material through upconversion of the triplet excitons into singlet excitons, so that the singlet state and the triplet state of the guest material are effectively utilized.

The traditional excimer generates a light emitting phenomenon by action of two same molecules, which is generally considered as being disadvantageous to energy transfer and light emission. Most of experiments show that generation of the excimer is disadvantageous to promotion of luminescent efficiency of the material. However, through the experiment, the disclosure discovers that reliable material matching and optimization can not only effectively utilize the excimer phenomenon and increase the efficiency of the device, but also obviously improve the lifetime of the device through reliable material matching.

### BRIEF DESCRIPTION OF THE DRAWINGS

FIG. 1 is a diagram of an embodiment of an organic electroluminescent device according to the disclosure.

In the figure, 1, substrate layer; 2, anode layer; 3, hole injection layer; 4, hole transport layer; 5, electron barrier layer; 6, luminescent layer; 7, hole barrier/electron transport layer; 8, electron injection layer; 9, cathode layer.

FIGS. 2˜4 are an emission spectrum of an exciplex formed by first and second organic compounds, an absorption spectrum of a third organic compound, an emission spectrum of an excimer formed by the third organic compound and an absorption spectrum of a guest doping material.

FIG. 5 shows lifetimes of an organic electroluminescent device prepared by examples when working at different temperatures.

### DESCRIPTION OF THE EMBODIMENTS

The disclosure will be specifically described in combination with accompanying drawings and examples, however, the scope of the disclosure is not limited by these preparation examples. In the context of the disclosure, unless otherwise stated, the singlet (S1) energy level means the lowest excited state energy level of the singlet state of a molecule, and the triplet (T1) energy level means the lowest excited state energy level of the triplet state of the molecule.

### Example 1

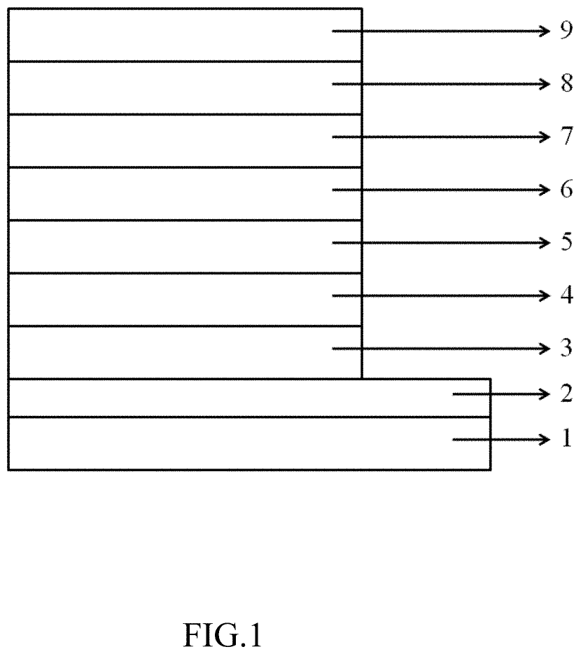

The structure of the organic electroluminescent device prepared in example 1 is as shown in FIG. 1, and the specific preparation process of the device is as follows:

An ITO anode layer 2 on a transparent glass substrate layer 1 was washed with deionized water, acetone and ethanol for 30 minutes under the ultrasonic condition respectively, and then treated in a plasma washer for 2 minutes; the ITO glass substrate was dried and then placed in a vacuum chamber until the vacuum degree was less than 1*10⁻⁶ Torr, an HT1 and P1 mixture having a film thickness of 10 nm was evaporated on the ITO anode layer 2, the mass ratio of HT1 to P1 was 97:3, and this layer was a hole injection layer 3; then, HT1 having a thickness of 50 nm was evaporated as a hole transport layer 4; then, EB1 having a thickness of 20 nm was evaporated as an electron barrier layer 5; further, a luminescent layer 6 having a thickness of 25 nm was evaporated, wherein the luminescent layer included a host material and guest doping dye, wherein selection of the first, second and third organic compounds of the host material is shown in Table 1. According to the mass percentages of the host material and the doping dye, the rate control was conducted through a film thickness gauge; ET1 and Liq having a thickness of 40 nm were further evaporated on the luminescent layer 6, and the mass ratio of ET1 to Liq was 1:1, and this organic material layer was used as a hole barrier/electron transport layer 7; LiF having a thickness of 1 nm was evaporated on the hole barrier/electron transport layer 7 in vacuum, which was an electron injection layer 8; the cathode A1 (80 nm) was evaporated in vacuum on the electron injection layer 8, which was a cathode layer 9. Different devices had different evaporated film thicknesses. The selection of specific materials in example 1 is shown in Table 1.

The preparation methods in examples 2-8 and comparative examples 1-8 adopt the method in example to obtain an organic electroluminescent device whose structure is similar to that in example; specific used materials are shown in Table 1.

The preparation methods in examples 9-16 and comparative examples 9-16 adopt the method in example to obtain an organic electroluminescent device whose structure is similar to that in example; specific used materials are shown in Table 2.

The preparation methods in examples 17-21 and comparative examples 17-21 adopt the method in example to obtain an organic electroluminescent device whose structure is similar to that in example; specific used materials are shown in Table 3.

It is necessary to note that the host form of the disclosure specifically has two manifestation forms: one host form is that the first organic compound, the second organic compound and the third organic compound form a certain proportion of mixture through three-source co-evaporation, for example (H1:H2:B-6)=(45:45:10) (25 nm). The other host form is that the first organic compound is evaporated, then the second organic and the third organic compound are co-evaporated; or the first organic compound and the third organic compound are co-evaporated, then the second organic compound is evaporated, for example (H1:H2:B-6)=(45:45:10) (25 nm). For conciseness, braces are not used in the tables.

TABLE 1

| | | | Hole | Hole | Electron | | Hole | Electron | |
|---|---|---|---|---|---|---|---|---|---|
| | | | injection | transport | barrier | Luminescent | barrier | injection | |
| Number | Substrate | Anode | layer | layer | layer | layer | layer | layer | Cathode |
| Example 1 | Glass | ITO | HT1:P1 | HT1 | EB1 | H1:H2:B-6:D-1 = | ET1:Liq | LiF | Al |
| | | | (10 nm) | (50 nm) | (20 nm) | 45:45:10:3 | (40 nm) | (1 nm) | (80 nm) |
| | | | | | | (25 nm) | | | |
| Example 2 | Glass | ITO | HT1:P1 | HT1 | EB1 | H1 | ET1:Liq | LiF | Al |
| | | | (10 nm) | (50 nm) | (20 nm) | (12.5 nm)/ | (40 nm) | (1 nm) | (80 nm) |
| | | | | | | H2:B-6:D-1 = | | | |
| | | | | | | 90:10:3 | | | |
| | | | | | | (12.5 nm) | | | |
| Example 3 | Glass | ITO | HT1:P1 | HT1 | EB1 | H1:H2:B-6:D-1 = | ET1:Liq | LiF | Al |
| | | | (10 nm) | (50 nm) | (20 nm) | 40:50:10:3 | (40 nm) | (1 nm) | (80 nm) |
| | | | | | | (25 nm) | | | |
| Example 4 | Glass | ITO | HT1:P1 | HT1 | EB1 | H3:H4:B-6:D-1 = | ET1:Liq | LiF | Al |
| | | | (10 nm) | (50 nm) | (20 nm) | 45:45:10:3 | (40 nm) | (1 nm) | (80 nm) |
| | | | | | | (25 nm) | | | |
| Example 5 | Glass | ITO | HT1:P1 | HT1 | EB1 | H1:H2:B-6:D-2 = | ET1:Liq | LiF | Al |
| | | | (10 nm) | (50 nm) | (20 nm) | 45:45:10:3 | (40 nm) | (1 nm) | (80 nm) |
| | | | | | | (25 nm) | | | |
| Example 6 | Glass | ITO | HT1:P1 | HT1 | EB1 | H1:B-6:D-2 = | ET1:Liq | LiF | Al |
| | | | (10 nm) | (50 nm) | (20 nm) | 90:10:3 | (40 nm) | (1 nm) | (80 nm) |
| | | | | | | (12.5 nm)/ | | | |
| | | | | | | H2 | | | |
| | | | | | | (12.5 nm) | | | |
| Example 7 | Glass | ITO | HT1:P1 | HT1 | EB1 | H1:H2:B-6:D-2 = | ET1:Liq | LiF | Al |
| | | | (10 nm) | (50 nm) | (20 nm) | 40:50:10:3 | (40 nm) | (1 nm) | (80 nm) |
| | | | | | | (25 nm) | | | |
| Example 8 | Glass | ITO | HT1:P1 | HT1 | EB1 | H3:H4:B-6:D-2 = | ET1:Liq | LiF | Al |
| | | | (10 nm) | (50 nm) | (20 nm) | 40:50:10:3 | (40 nm) | (1 nm) | (80 nm) |
| | | | | | | (25 nm) | | | |
| Comparative | Glass | ITO | HT1:P1 | HT1 | EB1 | H1:D-1 = | ET1:Liq | LiF | Al |
| example 1 | | | (10 nm) | (50 nm) | (20 nm) | 100:3 | (40 nm) | (1 nm) | (80 nm) |
| | | | | | | (25 nm) | | | |
| Comparative | Glass | ITO | HT1:P1 | HT1 | EB1 | H1:D-2 = | ET1:Liq | LiF | Al |
| example 2 | | | (10 nm) | (50 nm) | (20 nm) | 100:8 | (40 nm) | (1 nm) | (80 nm) |
| | | | | | | (25 nm) | | | |
| Comparative | Glass | ITO | HT1:P1 | HT1 | EB1 | H2:D-1 = | ET1:Liq | LiF | Al |
| example 3 | | | (10 nm) | (50 nm) | (20 nm) | 100:3 | (40 nm) | (1 nm) | (80 nm) |
| | | | | | | (25 nm) | | | |
| Comparative | Glass | ITO | HT1:P1 | HT1 | EB1 | H2:D-2 = | ET1:Liq | LiF | Al |
| example 4 | | | (10 nm) | (50 nm) | (20 nm) | 100:8 | (40 nm) | (1 nm) | (80 nm) |
| | | | | | | (25 nm) | | | |
| Comparative | Glass | ITO | HT1:P1 | HT1 | EB1 | Hl:H2:D-1 = | ET1:Liq | LiF | Al |
| example 5 | | | (10 nm) | (50 nm) | (20 nm) | 50:50:3 | (40 nm) | (1 nm) | (80 nm) |
| | | | | | | (25 nm) | | | |
| Comparative | Glass | ITO | HT1:P1 | HT1 | EB1 | H1 | ET1:Liq | LiF | Al |
| example 6 | | | (10 nm) | (50 nm) | (20 nm) | (12.5 nm)/ | (40 nm) | (1 nm) | (80 nm) |
| | | | | | | H2:D-1 = | | | |
| | | | | | | 100:3 | | | |
| | | | | | | (12.5 nm) | | | |
| Comparative | Glass | ITO | HT1:P1 | HT1 | EB1 | H1:H2:D-2 = | ET1:Liq | LiF | Al |
| example 7 | | | (10 nm) | (50 nm) | (20 nm) | 50:50:8 | (40 nm) | (1 nm) | (80 nm) |
| | | | | | | (25 nm) | | | |
| Comparative | Glass | ITO | HT1:P1 | HT1 | EB1 | H1:D-2 = | | | |
| example 8 | | | (10 nm) | (50 nm) | (20 nm) | 100:8 | ET1:Liq | LiF | Al |
| | | | | | | (12.5 nm)/ | (40 nm) | (1 nm) | (80 nm) |
| | | | | | | H2 | | | |
| | | | | | | (12.5 nm) | | | |

TABLE 2

| | | | Hole | Hole | Electron | | Hole | Electron | |
|---|---|---|---|---|---|---|---|---|---|
| | | | injection | transport | barrier | Luminescent | barrier | injection | |
| Number | Substrate | anode | layer | layer | layer | layer | layer | layer | Cathode |
| Example 9 | Glass | ITO | HT1:P1 | HT1 | EB1 | H5:H6:B-8:D-3 = | ET1:Liq | LiF | Al |
| | | | (10 nm) | (50 nm) | (60 nm) | 44:44:12:8 | (40 nm) | (1 nm) | (80 nm) |
| | | | | | | (40 nm) | | | |
| Example 10 | Glass | ITO | HT1:P1 | HT1 | EB1 | H5 | | | |
| | | | (10 nm) | (50 nm) | (60 nm) | (20 nm)/ | ET1:Liq | LiF | Al |
| | | | | | | H6:B-8:D-3 = | (40 nm) | (1 nm) | (80 nm) |
| | | | | | | 80:20:8 | | | |
| | | | | | | (20 nm) | | | |
| Example 11 | Glass | ITO | HT1:P1 | HT1 | EB1 | H5:H6:B-8:D-3 = | ET1:Liq | LiF | Al |
| | | | (10 nm) | (50 nm) | (20 nm) | 54:34:12:8 | (40 nm) | (1 nm) | (80 nm) |
| | | | | | | (40 nm) | | | |
| Example 12 | Glass | ITO | HT1:P1 | HT1 | EB1 | H7:H8:B-8:D-3 = | ET1:Liq | LiF | Al |
| | | | (10 nm) | (50 nm) | (60 nm) | 44:44:12:3 | (40 nm) | (1 nm) | (80 nm) |
| | | | | | | (40 nm) | | | |
| Example 13 | Glass | ITO | HT1:P1 | HT1 | EB1 | H5:H6:B-8:D-4 = | ET1:Liq | LiF | Al |
| | | | (10 nm) | (50 nm) | (60 nm) | 44:44:12:8 | (40 nm) | (1 nm) | (80 nm) |
| | | | | | | (40 nm) | | | |
| Example 14 | Glass | ITO | HT1:P1 | HT1 | EB1 | H5:B-8:D-4 = | | | |
| | | | (10 nm) | (50 nm) | (60 nm) | 88:12:8 | ET1:Liq | LiF | Al |
| | | | | | | (20 nm)/ | (40 nm) | (1 nm) | (80 nm) |
| | | | | | | H6 | | | |
| | | | | | | (20 nm) | | | |
| Example 15 | Glass | ITO | HT1:P1 | HT1 | EB1 | H5:H6:B-8:D-4 = | ET1:Liq | LiF | Al |
| | | | (10 nm) | (50 nm) | (20 nm) | 54:34:12:8 | (40 nm) | (1 nm) | (80 nm) |
| | | | | | | (25 nm) | | | |
| Example 16 | Glass | ITO | HT1:P1 | HT1 | EB1 | H7:H8:B-8:D-4 = | ET1:Liq | LiF | Al |
| | | | (10 nm) | (50 nm) | (20 nm) | 44:44:12:8 | (40 nm) | (1 nm) | (80 nm) |
| | | | | | | (25 nm) | | | |
| Comparative | Glass | ITO | HT1:P1 | HT1 | EB1 | H5:D-3 = | ET1:Liq | LiF | Al |
| example 9 | | | (10 nm) | (50 nm) | (60 nm) | 100:8 | (40 nm) | (1 nm) | (80 nm) |
| | | | | | | (40 nm) | | | |
| Comparative | Glass | ITO | HT1:P1 | HT1 | EB1 | H5:D-4 = | ET1:Liq | LiF | Al |
| example 10 | | | (10 nm) | (50 nm) | (60 nm) | 100:8 | (40 nm) | (1 nm) | (80 nm) |
| | | | | | | (40 nm) | | | |
| Comparative | Glass | ITO | HT1:P1 | HT1 | EB1 | H6:D-3 = | ET1:Liq | LiF | Al |
| example 11 | | | (10 nm) | (50 nm) | (60 nm) | 100:8 | (40 nm) | (1 nm) | (80 nm) |
| | | | | | | (25 nm) | | | |
| Comparative | Glass | ITO | HT1:P1 | HT1 | EB1 | H6:D-4 = | ET1:Liq | LiF | Al |
| example 12 | | | (10 nm) | (50 nm) | (60 nm) | 100:8 | (40 nm) | (1 nm) | (80 nm) |
| | | | | | | (40 nm) | | | |
| Comparative | Glass | ITO | HT1:P1 | HT1 | EB1 | H5:H6:D-3 = | ET1:Liq | LiF | Al |
| example 13 | | | (10 nm) | (50 nm) | (60 nm) | 100:8 | (40 nm) | (1 nm) | (80 nm) |
| | | | | | | (40 nm) | | | |
| Comparative | Glass | ITO | HT1:P1 | HT1 | EB1 | H5 | | | |
| example 14 | | | (10 nm) | (50 nm) | (60 nm) | (20 nm)/ | ET1:Liq | LiF | Al |
| | | | | | | H6:D-3 = | (40 nm) | (1 nm) | (80 nm) |
| | | | | | | 100:8 | | | |
| | | | | | | (20 nm) | | | |
| Comparative | Glass | ITO | HT1:P1 | HT1 | EB1 | H5:H6:D-4 = | ET1:Liq | LiF | Al |
| example 15 | | | (10 nm) | (50 nm) | (60 nm) | 50:50:8 | (40 nm) | (1 nm) | (80 nm) |
| | | | | | | (40 nm) | | | |
| Comparative | Glass | ITO | HT1:P1 | HT1 | EB1 | H5:D-4 = | ET1:Liq | LiF | Al |
| example 16 | | | (10 nm) | (50 nm) | (60 nm) | 100:8 | (40 nm) | (1 nm) | (80 nm) |
| | | | | | | (20 nm)/ | | | |
| | | | | | | H6 | | | |
| | | | | | | (20 nm) | | | |

TABLE 3

| | | | Hole | Hole | Electron | | Hole | Electron | |
|---|---|---|---|---|---|---|---|---|---|
| | | | injection | transport | barrier | Luminescent | barrier | injection | |
| Number | Substrate | anode | layer | layer | layer | layer | layer | layer | Cathode |
| Example 17 | Glass | ITO | HT1:P1 | HT1 | EB1 | H5:H6:B-3:D-5 = | ET1:Liq | LiF | Al |
| | | | (10 nm) | (50 nm) | (110 nm) | 42:42:16:4 | (40 nm) | (1 nm) | (80 nm) |
| | | | | | | (40 nm) | | | |
| Example 18 | Glass | ITO | HT1:P1 | HT1 | EB1 | H5:H6:B-3:D-5 = | ET1:Liq | LiF | Al |
| | | | (10 nm) | (50 nm) | (110 nm) | 50:34:16:4 | (40 nm) | (1 nm) | (80 nm) |
| | | | | | | (40 nm) | | | |
| Example 19 | Glass | ITO | HT1:P1 | HT1 | EB1 | H7:H8:B-3:D-5 = | ET1:Liq | LiF | Al |
| | | | (10 nm) | (50 nm) | (110 nm) | 50:34:16:4 | (40 nm) | (1 nm) | (80 nm) |
| | | | | | | (40 nm) | | | |
| Example 20 | Glass | ITO | HT1:P1 | HT1 | EB1 | H5 | ET1:Liq | LiF | Al |
| | | | (10 nm) | (50 nm) | (110 nm) | (20 nm)/ | (40 nm) | (1 nm) | (80 nm) |
| | | | | | | H6:B-3:D-5 = | | | |
| | | | | | | 84:16:4 | | | |
| | | | | | | (20 nm) | | | |
| Example 21 | Glass | ITO | HT1:P1 | HT1 | EB1 | H5:B-3:D-5 = | ET1:Liq | LiF | Al |
| | | | (10 nm) | (50 nm) | (110 nm) | 84:16:4 | (40 nm) | (1 nm) | (80 nm) |
| | | | | | | (20 nm)/ | | | |
| | | | | | | H6 | | | |
| | | | | | | (20 nm) | | | |
| Comparative | Glass | ITO | HT1:P1 | HT1 | EB1 | H5:D-5 = | ET1:Liq | LiF | Al |
| example 17 | | | (10 nm) | (50 nm) | (110 nm) | 100:4 | (40 nm) | (1 nm) | (80 nm) |
| | | | | | | (40 nm) | | | |
| Comparative | Glass | ITO | HT1:P1 | HT1 | EB1 | H6:D-5 = | ET1:Liq | LiF | Al |
| example 18 | | | (10 nm) | (50 nm) | (110 nm) | 100:4 | (40 nm) | (1 nm) | (80 nm) |
| | | | | | | (40 nm) | | | |
| Comparative | Glass | ITO | HT1:P1 | HT1 | EB1 | H5:H6:D-5 = | ET1:Liq | LiF | Al |
| example 19 | | | (10 nm) | (50 nm) | (110 nm) | 50:50:4 | (40 nm) | (1 nm) | (80 nm) |
| | | | | | | (40 nm) | | | |
| Comparative | Glass | ITO | HT1:P1 | HT1 | EB1 | H5 | ET1:Liq | LiF | Al |
| example 20 | | | (10 nm) | (50 nm) | (110 nm) | (20 nm)/ | (40 nm) | (1 nm) | (80 nm) |
| | | | | | | H6:D-5 = | | | |
| | | | | | | 100:4 | | | |
| | | | | | | (20 nm) | | | |
| Comparative | Glass | ITO | HT1:P1 | HT1 | EB1 | H5:D-5 = | ET1:Liq | LiF | Al |
| example 21 | | | (10 nm) | (50 nm) | (110 nm) | 100:4 | (40 nm) | (1 nm) | (80 nm) |
| | | | | | | (20 nm)/ | | | |
| | | | | | | H6 | | | |
| | | | | | | (20 nm) | | | |

Raw materials involved in Table 1, Table 2 and Table 3 are described as above, and the structures of the remaining raw materials are shown in the following formulas:

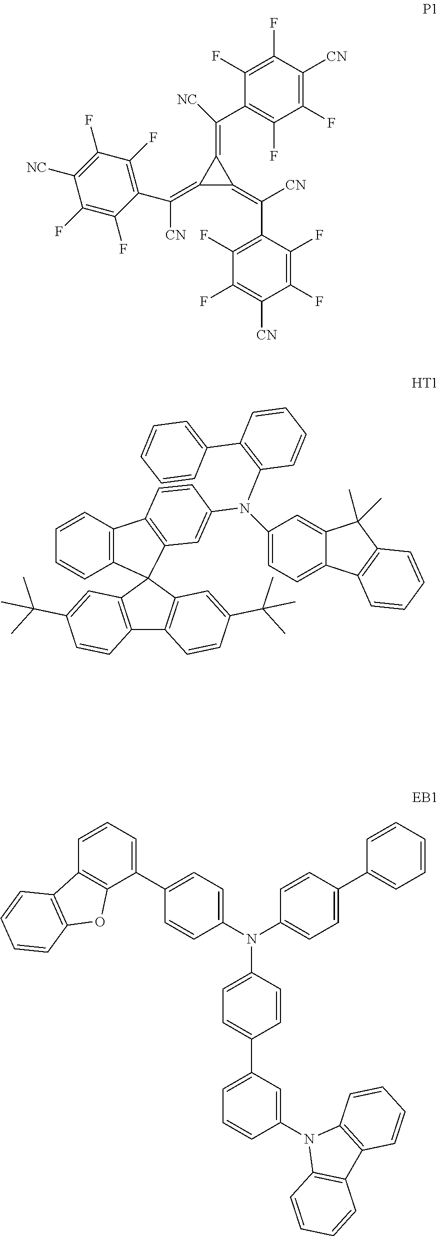

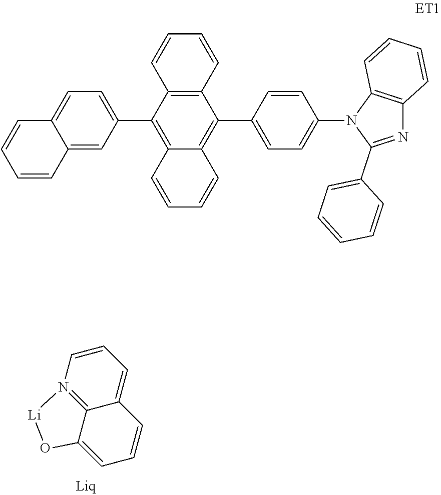

Wherein, the energy level relationships of host and guest materials are shown in Table 4.

TABLE 4

| | HOMO | LUMO | S1 | T1 |
|---|---|---|---|---|
| H1 | −5.85 eV | −2.51 eV | 3.35 eV | 2.90 eV |
| H2 | −6.10 eV | −2.82 eV | 3.30 eV | 2.85 eV |
| H3 | −5.78 eV | −2.42 eV | 3.50 eV | 2.89 eV |
| H4 | −6.20 eV | −2.75 eV | 3.43 eV | 2.83 eV |
| H5 | −5.64 eV | −2.25 eV | 3.28 eV | 2.75 eV |
| H6 | −5.98 eV | −2.50 eV | 3.42 eV | 2.80 eV |
| H7 | −5.68 eV | −2.20 eV | 3.50 eV | 2.72 eV |
| H8 | −6.18 eV | −2.90 eV | 3.32 eV | 2.68 eV |
| B-6 | −5.80 eV | −2.68 eV | 2.80 eV | 2.68 eV |
| B-8 | 5.74 eV | −2.75 eV | 2.70 eV | 2.58 eV |
| B-3 | 5.55 eV | −2.85 eV | 2.50 eV | 2.38 eV |
| D-1 | 5.48 eV | 2.70 eV | 2.60 eV | 1.8 eV |
| D-2 | 5.85 eV | 2.72 eV | 2.58 eV | 2.47 eV |
| D-3 | 5.90 eV | 3.40 eV | 2.40 eV | 2.30 eV |
| D-4 | 5.40 eV | 2.76 eV | 2.38 eV | 1.75 eV |
| D-5 | 5.30 eV | 3.35 eV | 2.15 eV | 1.6 eV |

The carrier mobility of the above selected materials is shown in Table 5 below.

TABLE 5

| Material | Hole mobility | Electron mobility |
|---|---|---|
| names | (cm²/V · S) | (cm²/V · S) |
| H1 | 2.12*10⁻³ | 1.63*10⁻⁶ |
| H2 | 5.01*10⁻⁶ | 3.21*10⁻⁴ |
| H3 | 5.09*10⁻³ | 2.17*10⁻⁵ |
| H4 | 2.14*10⁻⁴ | 3.01*10⁻⁶ |
| H5 | 6.25*10⁻³ | 1.86*10⁻⁵ |
| H6 | 4.66*10⁻³ | 3.01*10⁻⁵ |
| H7 | 3.69*10⁻³ | 2.07*10⁻⁴ |
| H8 | 5.62*10⁻⁵ | 2.53*10⁻³ |

The energy level of the above host material and the formed exciplexs are shown in Table 6 below.

TABLE 6

| | HOMO | LUMO | PL Peak | EL Peak |
|---|---|---|---|---|
| Material names | (eV) | (eV) | (nm) | (nm) |
| H1 | −5.85 | −2.51 | 380 | / |
| H2 | −6.10 | −2.82 | 385 | / |
| H3 | −5.78 | −2.42 | 387 | / |
| H4 | −6.20 | −2.75 | 341 | / |
| H5 | −5.64 | −2.25 | 450 | / |
| H6 | −5.98 | −2.50 | 388 | / |
| H7 | −5.68 | −2.20 | 458 | / |
| H8 | −6.18 | −2.90 | 502 | / |
| H1:H2 (50:50) | −5.85 | −2.82 | 460 | 458 |
| H1/H2 | −5.85 | −2.82 | 458 | 459 |
| H3:H4 (50:50) | −5.78 | −2.75 | 450 | 451 |
| H3:H4 | −5.78 | −2.75 | 449 | 448 |
| H5:H6 (50:50) | −5.64 | −2.50 | 485 | 483 |
| H5/H6 | −5.64 | −2.50 | 484 | 482 |
| H7:H8 (50:50) | −5.68 | −2.90 | / | 480 |
| H7/H8 | −5.68 | −2.90 | / | 481 |

Note: wherein, H1:H2 (50:50) represents a mixture of a first organic compound and a second organic compound having a mass ratio of 50:50 in a host material; H1/H2 represents an interface formed by the first organic compound and the second organic compound in the host material. Wherein, PL represents an optical excitation spectrum, and EL represents an electric field excitation spectrum.

The presence of the excimer is obtained by analysis via PL spectrum at a solution state and PL spectrum at a film state. Details are listed in Table 7 below:

TABLE 7

| | Plpeak | Plpeak |
|---|---|---|
| Material names | (nm)-solution | (nm)-film |
| B-3 | 495 | 540 |
| H5:H6:B-3 = 42:42:16 (60 nm) | / | 541 |
| H5:H6:B-3 = 50:34:16 (60 nm) | / | 539 |
| H7:H8:B-3 = 50:34:16 (60 nm) | / | 538 |
| B-6 | 435 | 465 |
| H1:H2:B-6 = 45:45:10 (60 nm) | / | 462 |
| H3:H4:B-6 = 40:50:10 (60 nm) | / | 463 |
| H1 (30 nm)/H2:B-6 = 90:10 | / | 459 |
| (30 nm) | | |
| B-7 | 460 | 510 |
| B-8 | 460 | 500 |
| H5 (30 nm)/H6:B-8 = 80:20 (30 nm) | / | 502 |
| H5:H6:B-8 = 54:34:12 (60 nm) | / | 501 |
| H7:H8:B-8 = 44:44:12 (60 nm) | / | 503 |
| B-11 | 460 | 525 |
| B-12 | 470 | 538 |

Note: Plpeak (nm)-solution is tetrahydrofuran solution having a concentration of 2*10⁻⁵ mol/L; Plpeak (nm)-film is a film formed by three-source co-evaporation of first, second and third organic compounds.

It can be seen from Table 7 that the blue shifting of the PL spectrum peak of the third organic compound in the tetrahydrofuran solution occurs compared with the PL spectrum peak at the film state, indicating that at the solution state, the third organic compound is acted by the solvent at the same time due to its low concentration, intermolecular accumulation is weak to difficultly generate the excimer; at the film state, due to closed intermolecular distance, intermolecular accumulation is relatively serious to generate the excimer.

In order to further describe the energy levels of the exciplex formed by the first organic compound and the second organic compound and the excimer formed by the third organic compound, the material is evaporated on the transparent quartz glass and then encapsulated. An Edinburgh fluorescence spectrometer is used (singlet and triplet energy levels of an FLS980 test material), and results are shown in Table 8 below:

TABLE 8

| | Singlet | Triplet |
|---|---|---|
| | energy | energy |
| | level S1 | level T1 |
| Material names | (eV) | (eV) |
| H1:H2 = 1:1 (60 nm) | 2.81 | 2.71 |
| H1 (30 nm)/H2 (30 nm) | 2.81 | 2.69 |
| H3:H4 = 1:1 (60 nm) | 2.88 | 2.76 |
| H3 (30 nm)/H4 (30 nm) | 2.87 | 2.77 |
| H5:H6 = 1:1 (60 nm) | 2.56 | 2.48 |
| H5 (30 nm)/H6 (30 nm) | 2.55 | 2.49 |
| H7:H8 = 1:1 (60 nm) | 2.60 | 2.51 |
| H7 (30 nm)/H8 (30 nm) | 2.59 | 2.50 |
| H1:H2:B-6 = 45:45:10 (60 nm) | 2.67 | 2.63 |
| H7:H8:B-8 = 44:44:12 (60 nm) | 2.49 | 2.37 |
| H5:H6:B-3 = 42:42:16 (60 nm) | 2.32 | 2.18 |

Note: H1:H2=1:1 (60 nm) represents a film having a thickness of 60 nm obtained by co-evaporation of H1 and H2 in a mass ratio of 1:1; H1 (30 nm)/H2 (30 nm) represents that H1 of 30 nm is evaporated, and then H2 of 30 nm is evaporated on H1; H1:H2:B-6=45:45:10 (60 nm) represents a film having a thickness of 60 nm obtained by co-evaporation of H1, H2 and B-6. Since H7:H8=1:1 (60 nm) cannot form the photoinduced exciplex, the electro-exciplex spectrum is tested by fabricating a device and electrified; H7:H8:B-8=44:44:12 (60 nm) undergo luminescent spectrum test by being made into a device.

It can be seen that, the singlet and triplet energy levels of the exciplex formed by the first organic compound and the second organic compound are both lower than those of the first organic compound and the second organic compound alone, and the singlet-triplet energy level difference is less than 0.2 eV. Meanwhile, the singlet and triplet energy levels of the excimer formed by doping the third organic compound into the first and second organic compounds are lower than those of the third organic compound itself, and the singlet-triplet energy level difference of the excimer is less than 0.3 eV.

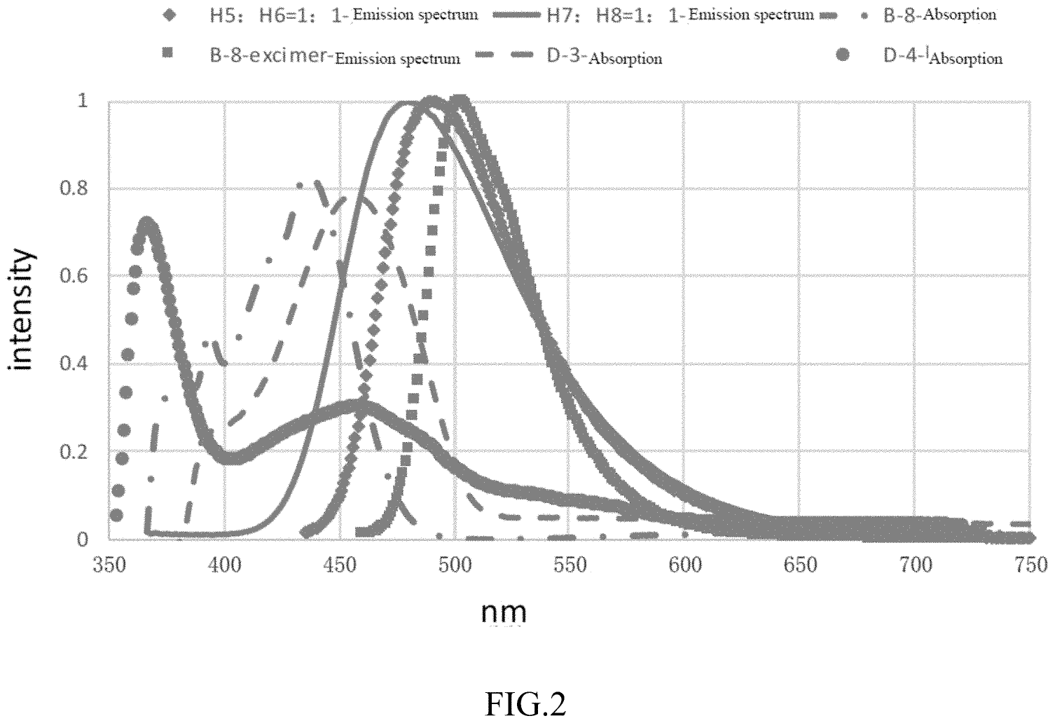

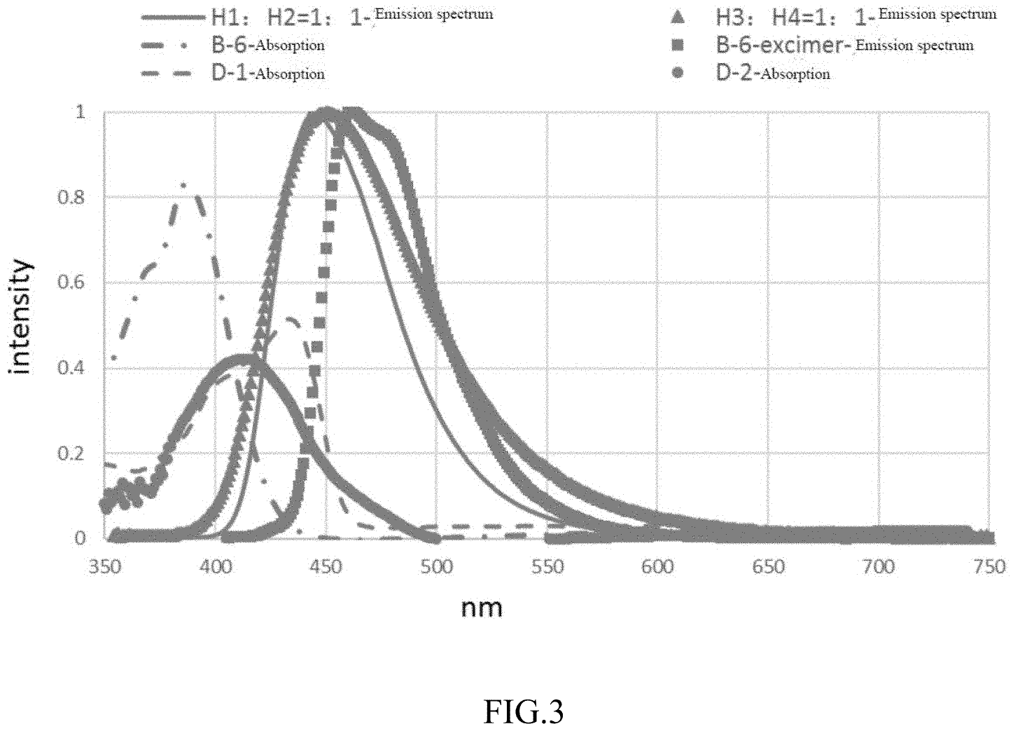

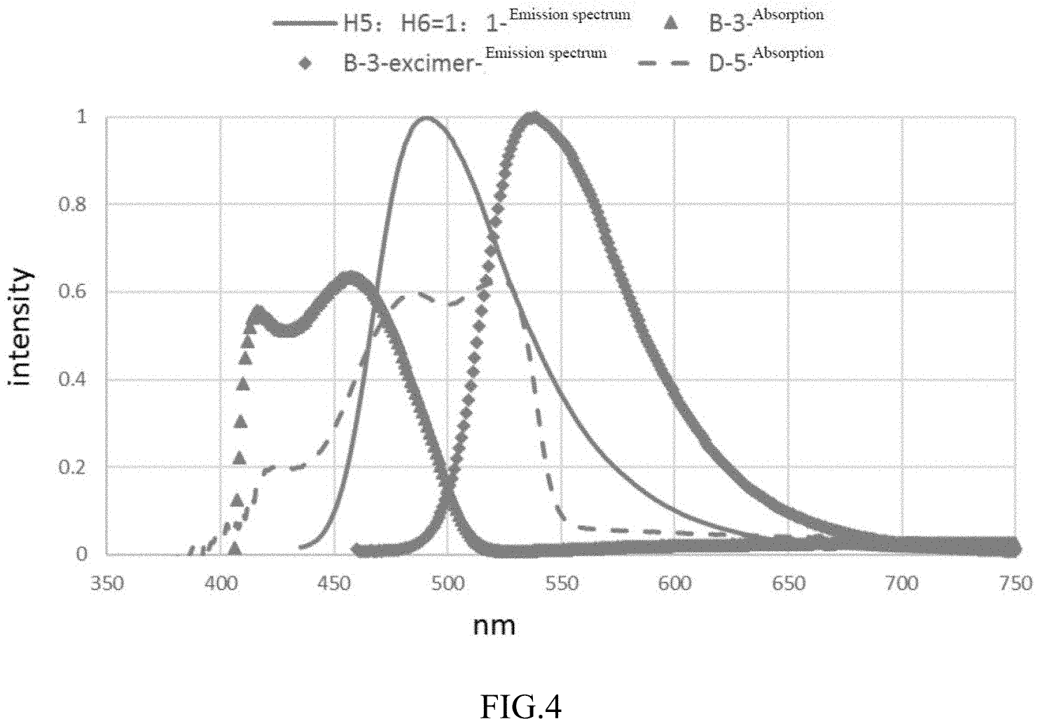

In order to research effectiveness of energy transfer between materials, whether absorption spectrums and emission spectrums are overlapped is observed by testing the emission spectrum of the exciplex formed by the first and second organic compounds, the absorption spectrum of the third organic compound, the emission spectrum of the excimer formed by the third organic compound and the absorption material of the guest doping material, specifically as shown in FIGS. 2, 3 and 4.

It can be seen from FIG. 2, FIG. 3 and FIG. 4 that the emission spectrum of the exciplex formed by the first and second organic compounds is effectively overlapped with the absorption spectrum of the third organic compound, ensuring that energy is transferred from the exciplex to the third organic compound. The emission spectrum of the excimer formed by the third organic compound is effectively overlapped with the absorption material of the guest doping material, ensuring that energy is transferred from the excimer to the guest doping material for emitting light.

The organic electroluminescent devices prepared in examples 1˜21 and comparative examples 1˜21 underwent performance test. Results are as shown in Table 9.

TABLE 9

| | | | Maximum | | |
|---|---|---|---|---|---|
| | Drive | External | external | LT90 | |
| | voltage | quantum | quantum | lifetime | Spectral |
| Device codes | (V) | efficiency | efficiency | (h) | color |
| Comparative | 5.2 | 4.5% | 5.5% | 20 | Blue |
| example 1 | | | | | |
| Comparative | 5.3 | 6.0% | 8.0% | 15 | Sky blue |
| example 2 | | | | | |
| Comparative | 5.5 | 4.8% | 5.6% | 18 | Blue |
| example 3 | | | | | |
| comparative | 5.6 | 6.2% | 8.2% | 10 | Sky blue |
| example 4 | | | | | |
| Comparative | 4.7 | 6.0% | 8.1% | 40 | Blue |
| example 5 | | | | | |
| Comparative | 4.6 | 5.8% | 6.5% | 38 | Blue |
| example 6 | | | | | |
| Comparative | 4.5 | 6.8% | 8.3% | 15 | Sky blue |
| example 7 | | | | | |
| comparative | 4.6 | 6.6% | 8.2% | 20 | Sky blue |
| example 8 | | | | | |
| Example 1 | 4.2 | 10.8 | 14.5% | 100 | Blue |
| Example 2 | 4.1 | 11.0% | 14.2% | 89 | Blue |
| Example 3 | 4.3 | 10.5% | 13.8% | 120 | Blue |
| Example 4 | 4.2 | 11.2% | 14.8% | 110 | Blue |
| Example 5 | 4.0 | 12.0% | 15.3% | 125 | Sky blue |
| Example 6 | 4.2 | 12.2% | 15.4% | 121 | Sky blue |
| Example 7 | 4.1 | 11.4% | 15.5% | 140 | Sky blue |
| Example 8 | 4.2 | 11.2% | 15.6% | 118 | Sky blue |
| Comparative | 5.1 | 10.2% | 16.0% | 60 | Green light |
| example 9 | | | | | |
| Comparative | 5.3 | 5.5% | 8.0% | 100 | Green light |
| example 10 | | | | | |
| Comparative | 5.2 | 10.4 | 16.0% | 65 | Green light |
| example 11 | | | | | |
| Comparative | 5.4 | 5.2% | 7.8% | 110 | Green light |
| example 12 | | | | | |
| Comparative | 4.2 | 12.5% | 18.0% | 85 | Green light |
| example 13 | | | | | |
| Comparative | 4.3 | 12.3 | 17.6% | 92 | Green light |
| example 14 | | | | | |
| Comparative | 4.0 | 5.7 | 8.3% | 123 | Green light |
| example 15 | | | | | |
| Comparative | 4.2 | 6.0 | 8.0% | 120 | Green light |
| example 16 | | | | | |
| Example 9 | 4.1 | 17.0% | 23.0% | 210 | Green light |
| Example 10 | 4.0 | 17.2% | 22.4% | 235 | Green light |
| Example 11 | 3.9 | 18.2% | 23.5% | 240 | Green light |
| Example 12 | 4.1 | 16.8 | 23.1 | 235 | Green light |
| Example 13 | 4.2 | 17.0 | 22.5 | 228 | Green light |
| Example 14 | 4.3 | 17.2 | 22.4 | 215 | Green light |
| example 15 | 4.0 | 17.7 | 23.0 | 207 | Green light |
| Example 16 | 4.2 | 17.5 | 23.2 | 244 | Green light |
| Comparative | 5.3 | 4.0 | 5.5 | 80 | Red light |
| example 17 | | | | | |
| Comparative | 5.2 | 3.8 | 5.6 | 85 | Red light |
| example 18 | | | | | |
| Comparative | 5.1 | 4.5 | 6.0 | 90 | Red light |
| example 19 | | | | | |
| Comparative | 5.2 | 4.7 | 5.9 | 104 | Red light |
| example 20 | | | | | |
| Comparative | 5.3 | 4.6 | 6.0 | 110 | Red light |
| example 21 | | | | | |
| Example 17 | 3.9 | 8.0 | 11.5 | 307 | Red light |
| Example 18 | 3.7 | 8.1 | 12.0 | 300 | Red light |
| Example 19 | 3.8 | 8.3 | 12.1 | 311 | Red light |
| Example 20 | 4.0 | 8.5 | 12.2 | 323 | Red light |
| Example 21 | 3.8 | 8.3 | 12.5 | 342 | Red light |

Note: in the above test results, the drive voltage, external quantum efficiency, LT90 lifetime and spectral color are all the test results of the device under the driving current density of 10 mA/cm²; the maximum external quantum efficiency is the maximum external quantum efficiency that can be achieved by the device in the test.

It can be seen from data in Table 9 that examples 1˜21 are compared with comparative examples 1˜21, the drive voltage of the device where the exciplex and the excimer are used as the host materials is obviously reduced than that of the device made of the single host material. Meanwhile, the drive voltage of the device where the exciplex and the excimer are used as the host materials is reduced, but not obviously reduced, than that of the device where the exciplex is used as a host. The main reasons are that the exciplex is capable of effectively transferring holes and electrons and reducing the injection barrier of the holes and electrons, thereby effectively reducing the drive voltage; the exciplex and the excimer are used as the host materials, in which the exciplex primarily plays a role of reducing the voltage, and the excimer has a certain ability of capturing electrons and holes, and reducing the voltage, but it just helps reduction in the voltage.

Meanwhile, the efficiency and lifetime of the device where the exciplex and the excimer are used as the host materials are obviously improved than those of the device where the single host material is used. The efficiency and lifetime of the device where the exciplex formed by the first and second organic compounds are matched with the excimer formed by boron-containing materials such as B-3 and B-6 are significantly improved mainly because the host material of the luminescent layer is formed by matching the exciplex with the excimer, the mixture or interface formed by the first and second organic compounds generate the exciplex under the condition that optical excitation or electric excitation, the exciplex can improve the efficiency of energy transfer to the guest material while reducing the concentration of triplet excitons of the host material, reducing the quenching effect of the triplet excitons and improving the lifetime of the device.

The third organic compound forms the excimer which is capable of effectively decreasing the concentration of the triplet excitons of the host material and reducing the singlet-exciton quenching and triplet-triplet quenching of the host material. The triplet excitons and singlet excitons of the excimer, due to being in a dual-molecule excitation form, are capable of improving the thermal stability and chemical stability of the molecule and preventing the decomposition of the material. Further, the excimer is capable of sufficiently transferring energy to the guest material through upconversion of the triplet excitons into singlet excitons, so that the singlet state and triplet state of the guest material are effectively utilized.

Such the structure matching is suitable for not only blue light devices but also green light devices and red light devices, indicating the universality of this device structure.

In addition, the second compound is a material having a carrier mobility different from that of the first compound, which can balance the carriers inside the host material, increase the recombination region of excitons and improve the efficiency of the device, and meanwhile can effectively solve the problem that the material color shifts under high current density so as to improve the stability of the light-emitting color of the device. The formed exciplex has a small difference between the triplex energy level and the singlet energy level, so that the triplet excitons can be rapidly converted into the singlet excitons, thereby reducing the quenching effect of the triplet excitons and promoting the stability of the device.

The singlet energy level of the formed exciplex is higher than that of the third organic compound, and the triplet energy level of the formed exciplex is higher than that of the third organic compound, which can effectively prevent energy from transferring back to the exciplex from the third organic compound, thereby further improving the efficiency and stability of the device.

The singlet energy level of the formed excimer is higher than that of the guest material, and the triplet energy level of the formed excimer is higher than that of the guest material, which can effectively prevent energy from transferring back to the host material from the guest material, thereby further improving the efficiency and stability of the device.

The third organic compound is an organic compound containing boron atoms, which are bonded with other atoms through sp2 hybrid form of boron. In the formed structure, since boron is an electron deficient atom, it has a strong electron absorbing ability, thereby increasing intermolecular coulomb force; meanwhile, due to the presence of boron atoms, the intermolecular rigidity is enhanced; the material easily forms a molecule aggregation effect and easily generates excimer luminescence.

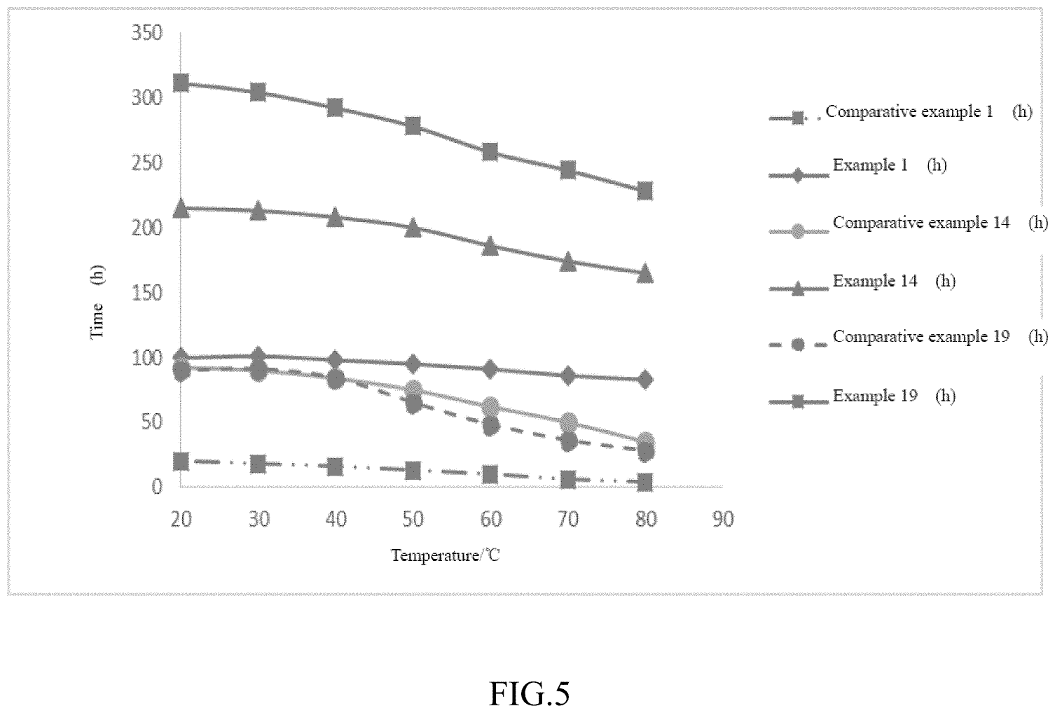

More further, the lifetimes of the OLED device prepared by the disclosure when working at different temperatures are relatively stable. The lifetimes of the devices in comparative example 1, example 1, comparative example 14, example 14, comparative example 19 and example 19 of the device are tested at −10˜80° C. (LT90). The obtained results are shown in Table 10 and FIG. 5.

TABLE 10

| | | | | | | | | | |
|---|---|---|---|---|---|---|---|---|---|
| Class (h)/Temperature ° C. | −10 | 10 | 20 | 30 | 40 | 50 | 60 | 70 | 80 |
| Comparative example 1(h) | 20 | 21 | 20 | 18 | 16 | 13 | 10 | 6 | 4 |
| Example 1 (h) | 102 | 103 | 100 | 101 | 98 | 95 | 91 | 86 | 83 |
| Comparative example 14 (h) | 93 | 92 | 92 | 90 | 84 | 75 | 62 | 50 | 35 |
| Example 14 (h) | 216 | 217 | 215 | 213 | 208 | 200 | 186 | 174 | 165 |
| Comparative example 19 (h) | 91 | 92 | 90 | 91 | 84 | 65 | 48 | 36 | 28 |
| Comparative example 19 (h) | 312 | 314 | 311 | 304 | 292 | 278 | 258 | 244 | 228 |

Note: the above test data are data of the device at 10 mA/cm².

Referring to Table 10 and FIG. 5, it can be found that compared with the traditional device matching, the device, where the host material is matched with the guest material, used in the structure of the present application, has little lifetime change at different temperatures; The lifetime of the device is kept unchanged at a higher temperature, indicating that the device with the present application structure matching has good device stability.

We claim:

1. An organic electroluminescent device, comprising a cathode, an anode, a luminescent layer between the cathode and the anode, a hole transport region between the anode and the luminescent layer and an electron transport region between the cathode and the luminescent layer; the luminescent layer comprising a host material and a guest material; wherein the host material of the luminescent layer comprises a first organic compound, a second organic compound and a third organic compound, a difference between the HOMO energy level of the first organic compound and the HOMO energy level of the second organic compound is greater than or equal to 0.2 eV, and a difference between the LUMO energy level of the first organic compound and the LUMO energy level of the second organic compound is greater than or equal to 0.2 eV;
the first organic compound and the second organic compound form a mixture or a laminated interface which generates an exciplex under the condition of optical excitation or electric field excitation; the emission spectrum of the exciplex and the absorption spectrum of the third organic compound are overlapped; the singlet energy level of the exciplex is higher than that of the third organic compound, and the triplet energy level of the exciplex is higher than that of the third organic compound; and the first organic compound and the second organic compound have different carrier transport characteristics;
the third organic compound is doped into the mixture or laminated interface formed by the first and second organic compounds and forms an intramolecular excimer; the singlet energy level of the excimer is less than that of the exciplex, and the triplet energy level of the excimer is less than that of the exciplex;
the guest material in the luminescent layer is a fluorescent organic compound, the singlet energy level of the guest material is less than that of the excimer, and the triplet energy level of the guest material is less than that of the excimer.

2. The organic electroluminescent device according to claim 1, wherein 0.3 eV≤|HOMO_{second organic compound}|−|HOMO_{first organic compound}|≤1.0 eV; 0.3 eV≤|LUMO_{second organic compound}|−|LUMO_{first organic compound}|≤1.0 eV; |HOMO_{third organic compound}|<|HOMO_{second organic compound}|, |LUMO_{third organic compound}|>|LUMO_{first organic compound}|; wherein, |HOMO| and |LUMO| represent absolute values of the energy levels of the compounds.

3. The organic electroluminescent device according to claim 1, wherein a difference between the triplet energy level and the singlet energy level of the exciplex formed by the first organic compound and the second organic compound is less than or equal to 0.2 eV.

4. The organic electroluminescent device according to claim 1, wherein the third organic compound forms the excimer, and a difference between the triplet energy level and the singlet energy level of the excimer is less than or equal to 0.2 eV.

5. The organic electroluminescent device according to claim 2, wherein the first organic compound and the second organic compound form a mixture in a mass ratio of 1:99˜99:1; the third organic compound is doped into the mixture formed by the first and second organic compounds; and a mass ratio of the third organic compound to the mixture formed by the first and second organic compounds is 1:99˜50:50.

6. The organic electroluminescent device according to claim 2, wherein the first organic compound and the second organic compound form a laminated structure having an interface, the first organic compound is located at a hole transport side, and the second organic compound is located at an electron transport side; the third organic compound is doped into the first organic compound layer or the second organic compound layer, and a mass ratio of the third organic compound to the first organic compound is 1:99˜50:50, or a mass ratio of the third organic compound to the second organic compound is 1:99˜50:50.

7. The organic electroluminescent device according to claim 1, wherein in the luminescent layer, the guest material is 0.5%˜15% by mass of the host material.

8. The organic electroluminescent device according to claim 1, wherein the hole mobility of the first organic compound is greater than an electron mobility, and the electron mobility of the second organic compound is greater than the hole mobility; and the first organic compound is a hole transfer type material, and the second organic compound is an electron transfer type material.

9. The organic electroluminescent device according to claim 1, wherein a difference between the singlet energy level and the triplet energy level of the guest material is less than or equal to 0.3 eV.

10. The organic electroluminescent device according to claim 1, wherein the third organic compound is a compound containing boron atoms; wherein the quantity of boron atoms is greater than or equal to 1, and the boron atoms are bonded with other elements through sp2 hybrid orbits;
a group connected with boron is one of a hydrogen atom, substituted or unsubstituted C1-C6 linear alkyl, substituted or unsubstituted C3-C10 cycloalkyl, substituted or unsubstituted C1-C10 heterocycloalkyl, substituted or unsubstituted C6-C60 aryl, and substituted or unsubstituted C3-C60 heteroaryl;
furthermore, the groups connected with boron atoms can be connected alone, or mutually and directly bonded to form a ring, or connected with boron after being connected with other groups to form the ring.

11. The organic electroluminescent device according to claim 10, wherein the quantity of boron atoms contained in the third organic compound is 1, 2 or 3.

12. The organic electroluminescent device according to claim 1, wherein the third organic compound has a structure as shown in general formula (1): 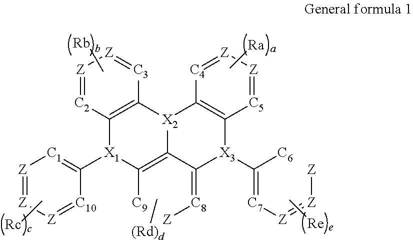
wherein, X₁, X₂ and X₃ each independently represent a nitrogen atom or a boron atom, and at least one of X₁, X₂ and X₃ is the boron atom; Z, on each occurrence, identically or differently represents N or C(R);
a, b, c, d and e each independently represent 0, 1, 2, 3, or 4;
at least one pair of C₁ and C₂, C₃ and C₄, C₅ and C₆, C₇ and C₈, and C₉ and C₁₀ can be connected to form a 5 to 7 membered ring structure;
R, on each occurrence, identically or differently represents H, D, F, Cl, Br, I, C(═O)R¹, CN, Si(R¹)₃, P(═O)(R¹)₂, S(═O)₂R¹, C1-C20 linear alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, SO or SO₂, and wherein one or more H atoms in the above groups can be substituted by D, F, Cl, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;
R¹, on each occurrence, identically or differently represents H, D, F, Cl, Br, I, C(═O)R², CN, Si(R²)₃, P(═O)(R²)₂, N(R²)S(═O)₂R², C1-C20 linear alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R²C═CR²—, —C≡C—, Si(R²)₂, C(═O), C═NR², —C(═O)O—, C(═O)NR²—, NR², P(═O)(R²), —O—, —S—, SO or SO₂, and wherein one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;
R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;
Ra, Rb, Rc and Rd each independently represent C1-C20 alkyl, branched C3-C20 alkaly or cycloalkyl, linear or branched C1-C20 alkyl substituted silyl, substituted or unsubstituted C6-C30 aryl, substituted or unsubstituted 5 to 30 membered heteroaryl, and substituted or unsubstituted C5-C30 arylamino;
under the condition that Ra, Rb, Rc and Rd groups are bonded with Z, Z is equal to C.

13. The organic electroluminescent device according to claim 1, wherein the third organic compound has a structure as shown in general formula (2): 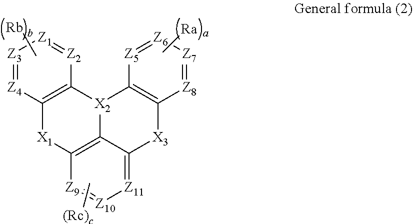
wherein, X₁ and X₃ each independently represent a single bond, B(R), N(R), C(R)₂, Si(R)₂, O, C═N(R), C═C(R)₂, P(R), P(═O)R, S or SO₂; X₂ independently represents a nitrogen atom or a boron atom, and at least one of X₁, X₂ and X₃ represents the boron atom;
Z₁-Z₁₁ independently represent nitrogen atoms or C(R), respectively;
a, b and c each independently represent 0, 1, 2, 3, or 4;
R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R¹C═CR¹—, —C≡C—, Si(R¹)₂, C(═O), C═NR¹, —C(═O)O—, C(═O)NR¹—, NR¹, P(═O) (R¹), —O—, —S—, SO or SO₂, and wherein one or more H atoms in the above groups can be substituted by D, F, C1, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;
R¹, on each occurrence, identically or differently represents H, D, F, Cl, Br, I, C(═O)R², CN, Si(R²)₃, P(═O)(R²)₂, N(R²)S(═O)₂R², linear C1-C20 alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R²C═CR²—, —C≡C—, Si(R²)₂, C(═O), C═NR², —C(═O)O—, C(═O)NR²—, NR², P(═O)(R²), —O—, —S—, SO or SO₂, and wherein one or more H atoms in the above groups can be substituted by D, F, Cl, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;
R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;
Ra, Rb and Rc each independently represent C1-C20 alkyl, branched C3-C20 alkyl or cycloalkyl, linear or branched C1-C20 alkyl substituted silyl, substituted or unsubstituted C6-C30 aryl, substituted or unsubstituted 5 to 30 membered heteroaryl, and substituted or unsubstituted C5-C30 arylamino;
under the condition that Ra, Rb and Rc groups are bonded with Z, Z is equal to C.

14. The organic electroluminescent device according to claim 1, wherein the third organic compound has a structure as shown in general formula (3): 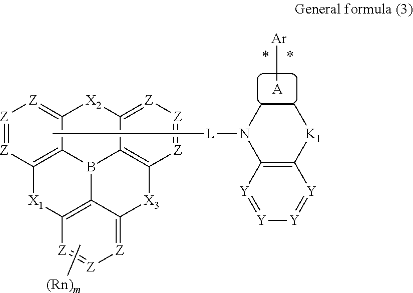
wherein, X₁, X₂ and X₃ each independently represent a single bond, B(R), N(R), C(R)₂, Si(R)₂, O, C═N(R), C═C(R)₂, P(R), P(═O)R, S or SO₂;
Z and Y at different positions independently represent C(R) or N, respectively;
K₁ represents one of a single bond, B(R), N(R), C(R)₂, Si(R)₂, O, C═N(R), C═C(R)₂, P(R), P(═O)R, S or SO₂, C1-C20 alkyl substituted alkylene, C1-C20 alkyl substituted silyl and C6-C20 aryl substituted alkylene; [symbol]
represents an aromatic group having a carbon atom number of 6˜20 or a heteroaromatic group having a carbon atom number of 3˜20;
m represents 0, 1, 2, 3, 4 or 5; L is selected from a single bond, a double bond, a triple bond, an aryl group having a carbon atom number of 6˜40 or a heteroaromatic group having a carbon atom number of 3˜40;
R, on each occurrence, identically or differently represents H, D, F, Cl, Br, I, C(═O)R¹, CN, Si(R¹)₃, P(═O)(R¹)₂, S(═O)₂R¹, linear C1-C20 alkyl or alkoxy group, branched or cyclic C3-C20 alkyl or alkoxy group, or C2-C20 alkenyl or alkynyl group, wherein the above groups each can be substituted by one or more groups R¹, and wherein one or more CH2 groups in the above groups can be substituted by —R¹C═CR¹—, —C≡C—, Si(R¹)₂, C(═O), C═NR¹, —C(═O)O—, C(═O)NR¹—, NR¹, P(═O)(R¹), —O—, —S—, SO or SO₂, and wherein one or more H atoms in the above groups can be substituted by D, F, C1, Br, I or CN, or an aromatic or heteroaromatic ring system having 5 to 30 aromatic ring atoms, the ring system can be substituted by one or more R¹ in each case, or an aryloxy or heteroaryl group having 5 to 30 aromatic ring atoms, the group can be substituted by one or more groups R¹, wherein two or more groups R can be connected to each other and form a ring;
R¹, on each occurrence, identically or differently represents H, D, F, C1, Br, I, C(═O)R², CN, Si(R²)₃, P(═O)(R²)₂, N(R²)S(═O)₂R², linear C1-C20 alkyl or alkoxy group, branched or cyclic C3-C20 alkyl or alkoxy group, or C2-C20 alkenyl or alkynyl group, wherein the groups each can be substituted by one or more groups R¹, and wherein one or more CH2 groups in the above groups can be substituted by —R²C═CR²—, —C≡C—, Si(R²)₂, C(═O), C═NR², —C(═O)O—, C(═O)NR²—, NR², P(═O)(R²), —O—, —S—, SO or SO₂, and wherein one or more H atoms in the above groups can be substituted by D, F, C1, Br, I or CN, or an aromatic or heteroaromatic group ring system having 5 to 30 aromatic ring atoms, the ring system can be substituted by one or more R² in each case, or an aryloxy or heteroaryl group having 5 to 30 aromatic ring atoms, the group can be substituted by one or more groups R², wherein two or more groups R¹ can be connected to each other and form a ring;
R², on each occurrence, identically or differently represents H, D, F or C1-C20 aliphatic, aromatic or heteroaromatic organic groups, wherein one or more H atoms can also be substituted by D or F; here, two or more substituents R² can be connected to each other and form a ring;
Rₙ independently represents substituted or unsubstituted C1-C20 alkyl, C1-C20 alkyl substituted silyl, substituted or unsubstituted C6-C30 aryl, substituted or unsubstituted 5 to 30 membered heteroaryl, and substituted or unsubstituted C5-C30 arylamino, respectively;
Ar represents substituted or unsubstituted C1-C20 alkyl, C1-C20 alkyl substituted silyl, substituted or unsubstituted C6-C30 aryl, substituted or unsubstituted 5 to 30 membered heteroaryl, and substituted or unsubstituted C5-C30 arylamino or a structure shown in general formula (4): 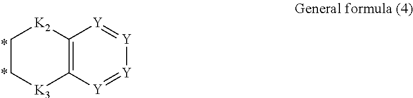
K₂ and K₃ independently represent one of a single bond, B(R), N(R), C(R)₂, Si(R)₂, O, C═N(R), C═C(R)₂, P(R), P(═O)R, S, S═O or SO₂, C1-C20 alkyl substituted alkylene, C1-C20 alkyl substituted silanylene and C6-C20 aryl substituted alkylene, respectively;
* represents ligation sites of general formula (4) and general formula (3).

15. The organic electroluminescent device according to claim 14, wherein in general formula (3), X₁, X₂ and X₃ each can also be independently absent, namely, none of atoms or bond linkages is each independently present at the positions represented by X₁, X₂ and X₃, and the atom or bond is present at the position of at least one of X₁, X₂ and X₃.

16. The organic electroluminescent device according to claim 1, wherein the guest material in the luminescent layer is as shown in general formula (5): 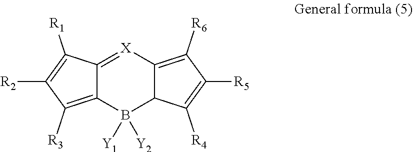
wherein, X represents the N atom or C—R₇;
R₁˜R₇ independently represent one of a hydrogen atom, substituted or unsubstituted C1-C20 alkyl, substituted or unsubstituted C3-C20 cycloalkyl, substituted or unsubstituted 3 to 20 membered heterocyclyl, substituted or unsubstituted C2-C20 alkylene, substituted or unsubstituted C3-C20 cycloalkylene, substituted or unsubstituted alkynyl, substituted or unsubstituted hydroxyl, substituted or unsubstituted alkoxyl, substituted or unsubstituted alkyl sulfide group, substituted or unsubstituted C6-C30 aryl, substituted or unsubstituted 5 to 30 membered heteroaryl, halogens, cyan, substituted or unsubstituted aldehyde group, substituted or unsubstituted carbonyl, substituted or unsubstituted carboxyl, substituted or unsubstituted oxycarbonyl, substituted or unsubstituted amido, substituted or unsubstituted amino, substituted or unsubstituted nitro, substituted or unsubstituted silyl, substituted or unsubstituted silyloxy, substituted or unsubstituted boryl and substituted or unsubstituted phosphine oxide;
R₁˜R₇ are each identical or different, and meanwhile R₁ and R₂, R₂ and R₃, R₄ and R₅, and R₅ and R₆ can be mutually bonded to form a cyclic structure having an atom number of 5˜30;
Y₁ and Y₂ can be identical or different; Y1 and Y₂ independently represent one of substituted or unsubstituted C1-C20 alkyl, substituted or unsubstituted C3-C20 cycloalkyl, substituted or unsubstituted 3 to 20 membered heterocyclyl, substituted or unsubstituted C2-C20 alkylene, substituted or unsubstituted C3-C20 cycloalkylene, substituted or unsubstituted C3-C20 alkenyl, substituted or unsubstituted alkynyl, substituted or unsubstituted hydroxyl, substituted or unsubstituted alkoxyl, substituted or unsubstituted alkyl sulfide group, substituted or unsubstituted C6-C30 aryl, substituted or unsubstituted 5 to 30 membered heteroaryl, halogens, cyan, substituted or unsubstituted aldehyde group, substituted or unsubstituted carbonyl, substituted or unsubstituted carboxyl, substituted or unsubstituted oxycarbonyl, substituted or unsubstituted amido, substituted or unsubstituted amino, substituted or unsubstituted nitro, substituted or unsubstituted silyl, substituted or unsubstituted silyloxy, substituted or unsubstituted boryl and substituted or unsubstituted phosphine oxide, respectively.

17. The organic electroluminescent device according to claim 16, wherein Y₁ and Y₂ in general formula (5) independently represent one of a fluorine atom, methoxyl, trifluromethyl, cyan and phenyl; X, R₁˜R₇ are consistent with those in claim 16.

18. The organic electroluminescent device according to claim 1, wherein the hole transport region comprises a combination of one or more of a hole injection layer, a hole transport layer and an electron barrier layer.

19. The organic electroluminescent device according to claim 1, wherein the electron transport region comprises a combination of one or more of an electron injection layer, an electron transport layer and a hole barrier layer.
